(19) United States
(12) Patent Application Publication
(10) Pub. No.: US 2025/0008637 A1
(43) Pub. Date: Jan. 2, 2025

(54) ISOLATION AND PROTECTION OF COMPUTING COMPONENTS FROM LIQUID IMMERSION COOLING FLUIDS

(71) Applicants: Casey Jamesen Carte, Portland, OR (US); Arpita Mitra, Chandler, AZ (US); Sandeep Ahuja, Portland, OR (US); Je-Young Chang, Tempe, AZ (US); Irving Castro Guzman, Tlajomulco de Zúñiga (MX); Ameya Limaye, Portland, OR (US); Mark A. MacDonald, Beaverton, OR (US)

(72) Inventors: Casey Jamesen Carte, Portland, OR (US); Arpita Mitra, Chandler, AZ (US); Sandeep Ahuja, Portland, OR (US); Je-Young Chang, Tempe, AZ (US); Irving Castro Guzman, Tlajomulco de Zúñiga (MX); Ameya Limaye, Portland, OR (US); Mark A. MacDonald, Beaverton, OR (US)

(21) Appl. No.: 18/883,503

(22) Filed: Sep. 12, 2024

(51) Int. Cl. H05K 1/02; H01L 23/10; H01L 23/367; H05K 7/20

(52) U.S. Cl. CPC H05K 1/0203; H01L 23/10; H01L 23/3675; H05K 7/20236

(57) ABSTRACT

Components in an integrated circuit component assembly located in a liquid immersion cooling environment are physically isolated from the immersion fluid. This physical isolation can be provided by seals between, for example, a heat sink attached to the integrated circuit components and an enclosure in which the integrated circuit components are located, a printed circuit board to which the integrated circuit components are attached and an integrated circuit component enclosure, a bolster plate and a heat sink, a ring that encompasses the integrated circuit components and a heat sink, and a ring and an integrated heat spreader that is part of an integrated circuit component. Alternatively, a conformal coating compatible with an immersion fluid can be applied to assembly components to act as a chemical reaction and physical barrier between the immersion fluid and integrated circuit component.

### BACKGROUND

In liquid immersion cooling, computing components are submerged in a thermally conductive dielectric liquid. Heat generated by the computing components is absorbed by the dielectric liquid and then dissipated into the environment by, for example, the dielectric liquid circulating through a heat exchanger.

### BRIEF DESCRIPTION OF THE DRAWINGS

FIG. 1 is a cross-sectional view of a first example assembly for use in a liquid immersion cooling environment.

FIG. 2 is a cross-sectional view of a second example assembly for use in a liquid immersion cooling environment.

FIG. 3 is a cross-sectional view of a third example assembly for use in a liquid immersion cooling environment.

FIG. 4 is a cross-sectional view of a fourth example assembly for use in a liquid immersion cooling environment.

FIG. 5 illustrates an exploded perspective view of an example socketed processor apparatus.

FIG. 6 is a cross-sectional view of a fifth example assembly for use in a liquid immersion cooling environment.

FIG. 7 is a cross-sectional view of a sixth example assembly for use in a liquid immersion cooling environment.

FIGS. 8A-8C are cross-sectional views of variations of a seventh example assembly for use in a liquid immersion cooling environment.

FIG. 9 is a cross-sectional view of an eighth example assembly for use in a liquid immersion cooling environment.

FIG. 10 is a cross-sectional view of a ninth example assembly for use in a liquid immersion cooling environment.

FIGS. 11A-11B are cross-sectional views of a tenth example assembly for use in a liquid immersion cooling environment.

FIG. 12 is a cross-sectional view of an eleventh example assembly for use in a liquid immersion cooling environment.

FIG. 13 is an example method of protecting and/or isolating components from immersion fluids.

FIG. 14 is a cross-sectional view of an integrated circuit die 1400 that may be included in any of the integrated circuit components disclosed herein.

FIG. 15 is a cross-sectional side view of an integrated circuit device assembly that may include a microelectronic assembly, in accordance with any of the embodiments disclosed herein.

FIG. 16 is a block diagram of an example electrical device that may include a microelectronic assembly, in accordance with any of the embodiments disclosed herein.

### DETAILED DESCRIPTION

Liquid immersion cooling is a thermal management option for integrated circuit components having a high thermal design power (TDP), such as those used in high-performance computing, cloud computing, and edge computing applications, or those having a low power use effectiveness (PUE). In liquid immersion cooling, integrated circuit components (along with printed circuit boards to which they are attached) are submerged in a tank containing a dielectric liquid (or immersion liquid). The dielectric liquid is thermally conductive, and the liquid absorbs heat generated by the integrated circuit components. A pump circulates the heated liquid through conduits or pipes to a heat exchanger, where heat absorbed by the liquid is dissipated into the environment. The pump then circulates the cooled liquid back to the tank where it is ready to absorb more heat from the integrated circuit components.

While being an attractive thermal management option in some cases, the use of liquid immersion cooling can have disadvantages. For example, as signal frequencies in integrated circuit components increase, the integrity of signals passing through a socket can be impacted due to differences in the dielectric constant and loss tangent between the immersion liquid and air. Various single-phase immersion cooling dielectric fluids, such as polyalphaolefins (PAOx), gas-to-liquid fluids/iso-paraffins, refined mineral oils, and bio-based fluids that have low viscosity (e.g., <30 cSt at 40° C.), low dielectric constant (e.g., ≤2.3 from 20 MHz to 40 GHz) and low loss tangent (e.g., ≤0.05), may be used to cool various components. However, since components are tuned to operate optimally in air they may not function as desired in these fluids, which have very different dielectric constants and loss tangents than air. In addition, the low molecular weight components of these immersion fluids, as well as additive packages used with these fluids, can result in material compatibility concerns between immersion fluids and the materials used in integrated circuit component packages (e.g., integrated heat spreader sealant, and DSC encapsulant) and system-level components (e.g., power supplies, power cables, network interface cards, solid state drives, labels).

To address these concerns, the chemical material compatibility between immersion fluids and integrated circuit components, printed circuit boards, and other electronic (and non-electronic components) that are to be submerged in the immersion fluid may need to be assessed whenever a new immersion fluid and/or component material are contemplated for use in a liquid immersion cooling solution. This can result in the expenditure of significant research and development resources on the part of integrated circuit component manufacturers. Further, some integrated circuit component manufacturers do not warranty their parts for use in systems employing liquid immersion cooling solutions. Thus, even if signal integrity and material compatibility concerns can be addressed, computing system manufacturers may still be reluctant to use liquid immersion cooling as a thermal management solution, especially given that integrated circuit components, in particular CPUs (central processing units) and GPUs (graphics processing units) are typically the most expensive components in a computing system.

Disclosed herein are technologies that isolate and/or protect computing components from immersion fluids via physical isolation and/or chemical reaction barriers. Physical isolation approaches include using a physical barrier to form a hermetically sealed volume in which the components to be isolated are located. This physical isolation allows for a sizeable air gap, ensuring that components tuned to operate optimally in air will not have any signal integrity issues when immersed. Various types of components can be isolated in a sealed volume, such as integrated circuit components attached to a printed circuit board having mezzanine connectors, an add-in card, or a motherboard. Removal of heat generated by integrated circuit components isolated in a sealed volume can be performed by a heat sink that can act as a lid to the sealed volume. In some embodiments, the heat sink is attached to an enclosure to define the volume within which protected computing components reside.

The protection of computing components via chemical reaction barriers involves the application of a conformal coating to the computing components. The coating acts as a chemical reaction barrier (as well as a physical barrier) between the components and an immersion fluid. The purpose of the coating is to eliminate or at least slow down the chemical degradation of the components due to exposure of the components to the immersion fluid. The conformal coatings can have a thickness in the range of about 1 micron to 50 microns and can be applied using a suitable coating process. These coatings can be: (1) hydrophobic or super-hydrophobic as well as oleophobic or super-oleophobic; (2) amphiphobic or super-amphiphobic; (3) omniphobic; or (4) any combination of (1), (2), and (3).

The immersion fluid isolation and protection technologies disclosed herein have at least the following advantages. First, by isolating and/or protecting computing components from immersion fluids, the development of computing components (cables, connectors, etc.), which can involve the expenditure of significant resources, can be avoided. Second, physical isolation reduces the impact of immersion fluid on signal integrity, if not eliminating it. Third, the development of software solutions that may mitigate the impact of immersion fluid exposure on signal integrity for signals passing through immersed cables, connectors, etc., which can also involve the expenditure of significant resources, can be avoided. Fourth, the chemical reaction barrier provided by the coatings can reduce the risk of material performance degradation, corrosion, and electric failures of integrated circuit components and other printed circuit board components due to chemical reactions between the components and immersion fluids. This can extend the life of these components. Fifth, they may prompt a computing system manufacturer to use components in a liquid immersion cooling environment that do not have a warranty that covers usage of the component in a liquid immersion cooling environment. This can expand the range of computing system offerings provided by the computing system manufacturer.

In the following description, specific details are set forth, but embodiments of the technologies described herein may be practiced without these specific details. Well-known circuits, structures, and techniques have not been shown in detail to avoid obscuring an understanding of this description. Phrases such as “an embodiment,” “various embodiments,” “some embodiments,” and the like may include features, structures, or characteristics, but not every embodiment necessarily includes the particular features, structures, or characteristics.

Some embodiments may have some, all, or none of the features described for other embodiments. “First,” “second,” “third,” and the like describe a common object and indicate different instances of like objects being referred to. Such adjectives do not imply objects so described must be in a given sequence, either temporally or spatially, in ranking, or in any other manner. “Connected” may indicate elements are in direct physical or electrical contact with each other and “coupled” may indicate elements co-operate or interact with each other, but they may or may not be in direct physical or electrical contact. Furthermore, the terms “comprising,” “including,” “having,” and the like, as used with respect to embodiments of the present disclosure, are synonymous. Values modified by the word “about” include values within +/−10% of the listed values and values listed as being within a range include those within a range from 10% less than the listed lower range limit and 10% greater than the listed higher range limit. Terms modified by the word “substantially” include arrangements, orientations, spacings, or positions that vary slightly from the meaning of the unmodified term.

In the following description, for purposes of explanation, numerous specific details are set forth in order to provide a thorough understanding thereof. It may be evident, however, that the novel embodiments can be practiced without these specific details. In other instances, well-known structures and devices are shown in block diagram form in order to facilitate a description thereof. The intention is to cover all modifications, equivalents, and alternatives within the scope of the claims.

Certain terminology may also be used herein for the purpose of reference only, and thus are not intended to be limiting. For example, terms such as “upper,” “lower,” “above,” “below,” “bottom,” and “top” refer to directions in the Figures to which reference is made. Terms such as “front,” “back,” “rear,” and “side” describe the orientation and/or location of layers, components, portions of components, etc., within a consistent but arbitrary frame of reference, which is made clear by reference to the text and the associated Figures describing the layers, component, portions of components, etc. under discussion. Such terminology may include the words specifically mentioned above, derivatives thereof, and words of similar import.

As used herein, the phrase “located on” or “on” in the context of a first layer or component located on or on a second layer or component refers to the first layer or component being directly physically attached to the second part or component (no layers or components between the first and second layers or components) or physically attached to the second layer or component with one or more intervening layers or components.

As used herein, the term “adjacent” refers to layers or components that are in physical contact with each other. That is, there is no layer or component between the stated adjacent layers or components. For example, a layer X that is adjacent to a layer Y refers to a layer that is in physical contact with layer Y.

As used herein, the term “integrated circuit component” refers to a packaged or unpacked integrated circuit product. A packaged integrated circuit component comprises one or more integrated circuit dies mounted on a package substrate with the integrated circuit dies and package substrate encapsulated in a casing material, such as a metal, plastic, glass, or ceramic. In one example, a packaged integrated circuit component contains one or more processor units mounted on a substrate with an exterior surface of the substrate comprising a solder ball grid array (BGA). In one example of an unpackaged integrated circuit component, a single monolithic integrated circuit die comprises solder bumps attached to contacts on the die. The solder bumps allow the die to be directly attached to a printed circuit board. An integrated circuit component can comprise one or more of any computing system component described or referenced herein or any other computing system component, such as a processor unit (e.g., system-on-a-chip (SoC), processor core, graphics processor unit (GPU), accelerator, chipset processor), I/O controller, memory, or network interface controller.

As used herein, the term “electronic component” can refer to an active electronic component (e.g., processing unit, memory, storage device, FET) or a passive electronic component (e.g., resistor, inductor, capacitor).

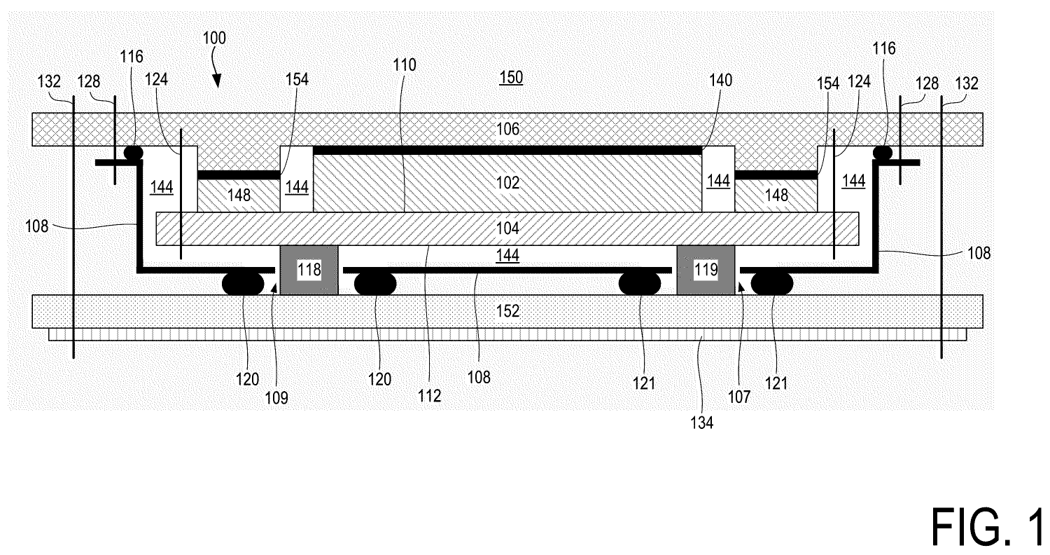

As used herein, the phrase “electrically coupled” refers to the presence of one or more electrically conductive paths between components that are recited as being electrically coupled. For example, with reference to FIG. 1, the integrated circuit component 102 is electrically coupled to the printed circuit board 152 due to the presence of electrically conductive paths through the printed circuit board 104 and connectors and 118 and 119 between solder bumps on the integrated circuit component 102 and pads on the printed circuit board 152.

Reference is now made to the drawings, which are not necessarily drawn to scale, wherein similar or the same numbers may be used to designate the same or similar parts in different figures. The use of similar or same numbers in different figures does not mean all figures including similar or same numbers constitute a single or same embodiment. Like numerals having different letter suffixes may represent different instances of similar components. The drawings illustrate generally, by way of example, but not by way of limitation, various embodiments discussed in the present document.

FIG. 1 is a cross-sectional view of a first example assembly for use in a liquid immersion cooling environment. The assembly 100 comprises integrated circuit components 102 and 148 attached to a top surface 110 of a printed circuit board 104. Connectors 118 and 119 are attached to a bottom surface 112 of the printed circuit board 104 and connect the printed circuit board 104 to a printed circuit board 152. The connectors 118 and 119 carry power, ground, and other signals between the printed circuit boards 104 and 152 and thereby electrically couple printed circuit board 104 to printed circuit board 152. The printed circuit board 152 can be a motherboard, a main board, or a system board of a computing system. The integrated circuit components 148 can be memory integrated circuit components, voltage regulators, or any other heat-producing component that requires cooling. The integrated circuit component 102 can be a central processing unit (CPU), graphics processing unit (GPU), neural network processing unit (NPU), an artificial intelligence (AI) accelerator, any type of processor described or referenced herein, or any other type of processor. In other embodiments, an assembly can comprise any number of processors being of the same type of processors or a plurality of different types of processors. The connectors 118 and 119 are illustrated as mezzanine connectors but in other embodiments, the connectors 118 and 119 can be any suitable connector and the assembly 100 can take on different form factors. For example, in other embodiments, an assembly can comprise an add-in card that connects to a motherboard.

The assembly 100 further comprises a heat sink 106 attached to the printed circuit board 104 by fasteners 124. The assembly 100 is shown as being located in a liquid immersion cooling environment and is surrounded by a dielectric liquid (or immersion fluid) 150. The immersion liquid 150 can be located in an immersion tank (not shown). The heat sink 106 is located on integrated circuit components 102 and 148 with layers 140 and 154 of thermal interface material positioned between the heat sink 106 and integrated circuit components 102 and 148, respectively. The heat sink 106, as well as any other heat sink described or referenced herein, can be a natural convention-cooled heat sink (e.g., a fin-type heat sink, a heat pipe, a vapor chamber) or a forced convention-cooled or targeted forced convection-cooled heat sink (e.g., a cold plate). If the heat sink is a forced convection-cooled heat sink, such as a cold plate, the heat sink can be part of a liquid cooling system that uses either a single-phase or two-phase working fluid and that comprises tubing or pipes to carry the liquid coolant between the cold plate, a heat exchanger, and a pump. The heat exchanger can comprise a cooling tower, chiller, or other suitable heat exchanger. If the heat sink is a cold plate, the cold plate can be any suitable type of cold plate, such as a tubed cold plate or a cold plate comprising internal fins or channels (e.g., microchannels), and be made of any suitable material, such as copper, aluminum, or stainless steel that is chemically compatible with immersion and working fluids.

The heat sink 106 is further attached to an enclosure 108 by fasteners 128. The enclosure 108 is tub-shaped but can have other shapes in other embodiments. The heat sink 106 and enclosure 108 define a volume in which the integrated circuit components 102 and 148, the printed circuit board 104, and a portion of the connectors 118 and 119 are located. The attachment of the heat sink 106 to the enclosure 108 forms a seal between the heat sink 106 and the enclosure 108 that prevents immersion fluid 150 from entering the volume. Portions 144 of the volume not occupied by components of the assembly 100 can be occupied by air. In the embodiment illustrated in FIG. 1, the seal between the heat sink 106 and the enclosure 108 comprises a gasket 116. Connectors 118 and 119 extend through openings 109 and 107 in the enclosure 108.

Then heat sink 106 is also attached to the second printed circuit board 152 by fasteners 132. The fasteners 132 are attached to a backplate 134, which provides mechanical reinforcement for the printed circuit board 152. The attachment of the heat sink 106 to the enclosure 108 forms another second seal, this one between the enclosure 108 and the printed circuit board 152, that also prevents immersion fluid 150 from entering the volume. This second seal also prevents connectors 118 and 119 from being exposed to the immersion fluid 150. The seal between enclosure 108 and printed circuit board 152 comprises gaskets 120 and 121, with gasket 120 encompassing connector 118 and gasket 121 encompassing connector 119.

In some embodiments, the assembly 100 can be assembled as follows. First, a first subassembly (or subcomponent) comprising the printed circuit board 104 populated with the connectors 118 and 119 and the integrated circuit components 102 and 148 (with thermal interface material layers 140 and 154 applied to top surfaces of the integrated circuit components 102 and 148, respectively) is attached to the heat sink 106 to create a second subassembly. Second, the second subassembly is placed in and attached to the enclosure 108, with attachment of the heat sink 106 to the enclosure 108 creating the seal comprising gasket 116. Third, the second subassembly is attached to the motherboard 152 to create the assembly 100. The assembly 100 is created by attachment of the connectors 118 and 119 and the heat sink 106 to the motherboard 152. The provision and formation of the first subassembly, second subassembly, and the assembly 100 can be performed by various parties. For example, an integrated circuit component manufacturer can provide the first subassembly to a computing system manufacturer that then assembles the second subassembly and the assembly 100. In another example, the integrated circuit component manufacturer assembles the first assembly and the second subassembly, and a computing system manufacturer assembles the assembly 100.

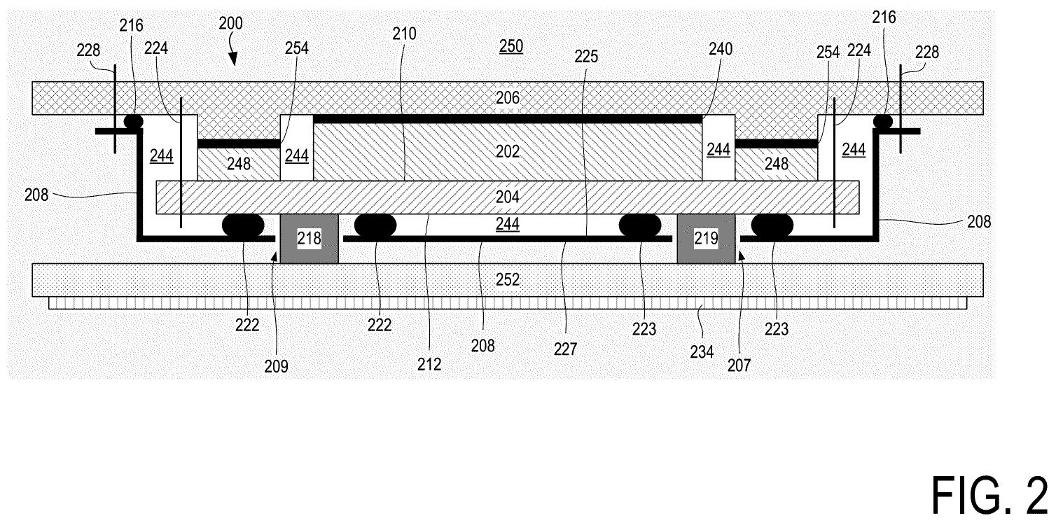

FIG. 2 is a cross-sectional view of a second example assembly for use in a liquid immersion cooling environment. The assembly 200 is similar to assembly 100 with the components and features in FIG. 2 being described by their like-numbered counterpart component or feature in FIG. 1 (i.e., integrated circuit component 202 is described by integrated circuit component 102) but with one difference being the gaskets 222 and 223 encompassing the connectors 218 and 219 being positioned on an inner surface of the enclosure 208 (surface 225) instead of an outer surface of the surface (surface 227). That is, gaskets 222 and 223 located between the enclosure 208 and the printed circuit board 204 and encompassing connectors 218 and 219 prevent the immersion liquid 250 from entering the volume defined by the heat sink 206 and the enclosure 208. A consequence of the difference in the location of the gaskets 222 and 223 relative to the location of the gaskets 120 and 121 of FIG. 1 is that the connectors 218 and 219 of assembly 200 are exposed to the immersion liquid 250. FIG. 2 does not illustrate fasteners attaching the heat sink 206 to the printed circuit board 252 as gaskets 222 and 223 are compressed via the load resulting from attachment of the heat sink 206 to the enclosure 208 by fasteners 216. The subassembly comprising integrated circuit components 202 and 248, printed circuit board 204, heat sink 206, and enclosure 208 can be attached to the printed circuit board 252 solely via attachment of the connectors 218 and 219 to the printed circuit board 252.

In some embodiments, the assembly 200 can be assembled as follows. First, a first subassembly comprising the printed circuit board 204 populated with the connectors 218 and 219, integrated circuit components 202 and 248 (with thermal interface material layers 240 and 254 applied to top surfaces of the integrated circuit components 202 and 248, respectively) is attached to the heat sink 206 to create a second subassembly. Second, the second subassembly is attached to the enclosure 208 via attachment of the heat sink 206 to the enclosure 208, with attachment of the heat sink 206 to the enclosure 208 creating a first seal comprising gasket 216 and a set of second seals comprising gaskets 222 and 223 to prevent immersion liquid 250 from entering a volume defined by the heat sink 206 and the enclosure 208. Third, the second subassembly is attached to the printed circuit board 252 by attachment of connectors 218 and 219 to the printed circuit board 252. The provision and formation of the first subassembly, second subassembly, and the assembly 200 can be performed by various parties. For example, an integrated circuit component manufacturer can provide the first subassembly to a computing system manufacturer that then assembles the second subassembly and the assembly 200. In another example, the integrated circuit component manufacturer assembles the first assembly and the second subassembly, and a computing system manufacturer assembles the assembly 200.

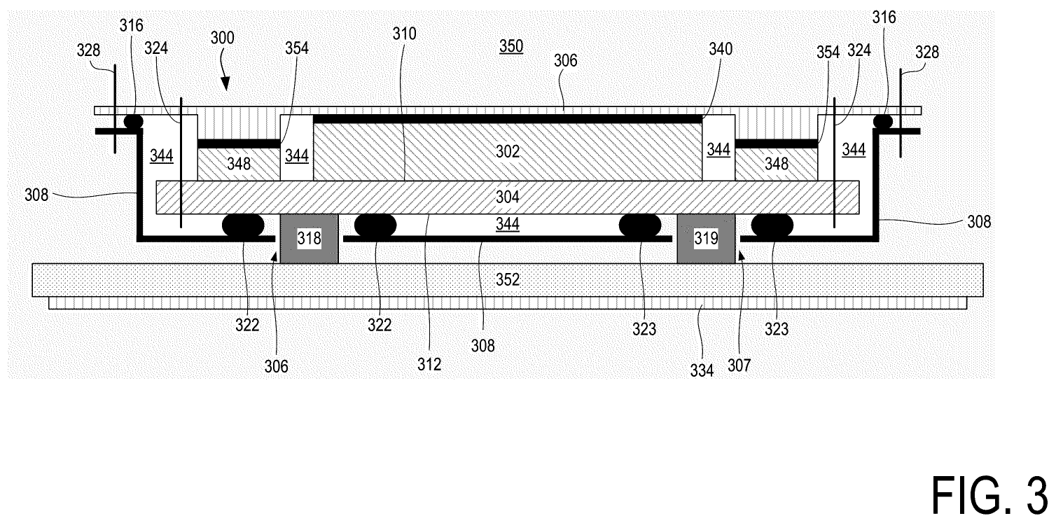

FIG. 3 is a cross-sectional view of a third example assembly for use in a liquid immersion cooling environment. The assembly 300 is similar to assembly 200 with the components and features in FIG. 3 described by their like-numbered counterpart component or feature in FIG. 2 (i.e., integrated circuit component 302 is described by integrated circuit component 202). One difference between the assembly 300 and the assembly 200 is the attachment of a lid 306 (instead of a heat sink) to the printed circuit board 304 and the enclosure 308. The lid 306 can comprise a metal or another suitable thermally conductive material and a heat sink can be attached to the lid. The assembly 300 can offer flexibility over the assembly 200 in that if an integrated circuit component manufacturer supplies a subassembly comprising the integrated circuit components 302 and 348, printed circuit board 304, connectors 318 and 319, and lid 306 to a computing system manufacturer, the computing system manufacturer can attach a heat sink of their choosing to the subassembly. Although the assembly 300 is shown as a variation of the assembly 200, with the heat sink 206 replaced with the lid 306, any other assemblies disclosed herein (e.g., assemblies 100, 400) can comprise a lid to which a heat sink can be attached. As used herein, the term “lid” can refer to a heat sink (e.g., 106, 206) or to a thermally conductive component to which a heat sink is attached (e.g., 306). That is, a lid can be a single component or two (or more) attached components. Either way, a lid refers to a component that attaches to an enclosure to define a volume in which integrated circuit components are located for isolation from immersion fluid.

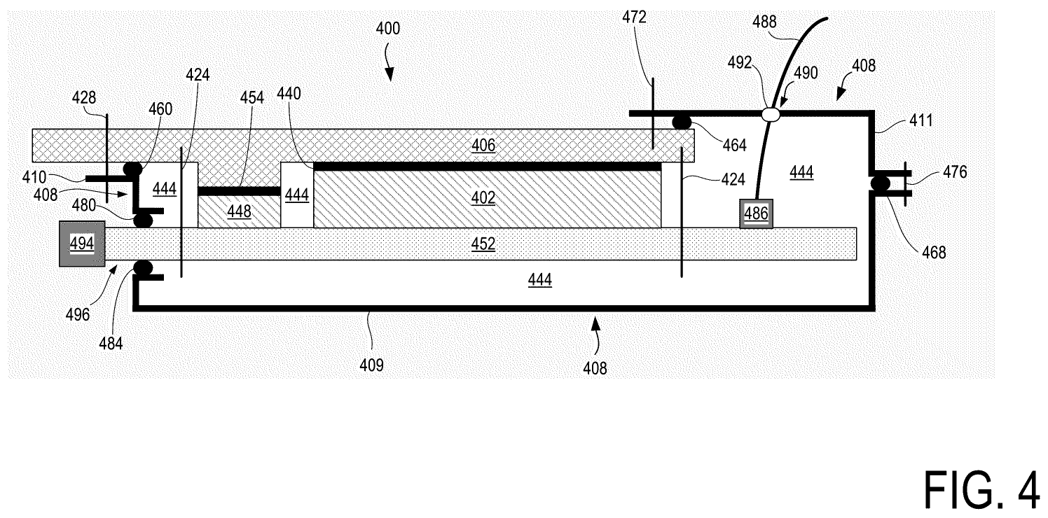

FIG. 4 is a cross-sectional view of a fourth example assembly for use in a liquid immersion cooling environment. The assembly 400 varies from the assemblies 100, 200, and 300 in that the integrated circuit components located in the volume sealed from immersion fluid are attached to a portion of a printed circuit board that is also located in the volume. The assembly 400 comprises integrated circuit components 402 and 448 attached to a printed circuit board 452, which can be a motherboard. The integrated circuit component 448 can be a memory component and the integrated circuit component 402 can be any type of processor described or referenced herein, or any other type of processor. In other embodiments, the assembly 400 assembly can comprise any number of processors with the processors all being the same type or comprising a plurality of different types of processors. The assembly 400 further comprises a heat sink 406 attached to the printed circuit board 452 by fasteners 424. The assembly 400 is shown as being located in a liquid immersion cooling environment and is surrounded by an immersion liquid 450. The dielectric liquid 450 can be located in an immersion tank (not shown).

The heat sink 406 is located on integrated circuit components 402 and 448 with layers 440 and 454 of thermal interface material positioned between the heat sink 406 and the integrated circuit components 402 and 448, respectively. The heat sink 406 is further attached to an enclosure 408 that comprises a first portion 409, a second portion 410, and a third portion 411. The heat sink 406 and the enclosure 408 define a volume in which the integrated circuit components 402 and 448 and printed circuit board 452 are located. The heat sink 406 is attached to the second portion 409 and the third portion 411 of the enclosure 408 by fasteners 424 and 428, respectively. Attachment of the heat sink 406 to the second portion 409 of the enclosure 408 comprises a first seal and attachment of the heat sink 406 to the third portion 411 of the enclosure 408 comprises a second seal. The first and second seals comprise gaskets 460 and 464, respectively.

The third portion 411 of the enclosure 408 is attached to the first portion 409 of the enclosure 408 by fastener 476. Attachment of the third portion 411 to the first portion 409 forms a third seal that comprises a gasket 468. The first and second portions 409 and 410 of the enclosure form fourth and fifth seals with the printed circuit board 452, the fourth and fifth seals comprising gaskets 480 and 484, respectively. Together, the first through fifth seals prevent immersion fluid 450 from entering the volume defined by the heat sink 406 and the enclosure 408 and thus isolate the integrated circuit components 402 and 448 from the immersion fluid 450.

The assembly 400 further comprises a connector 486 attached to the portion of the printed circuit board 452 isolated from the immersion fluid 450. A cable 488 is attached to the connector 486 and extends through an opening 490 in the third portion 411 of the enclosure 408. The opening 490 is sealed with a gasket, epoxy, or other suitable seal to prevent immersion fluid 450 from leaking into the volume 444. Although FIG. 4 illustrates a lone connector 486 attached to the printed circuit board 452 in the volume 444, in other embodiments more or no connectors can be attached to the portion of the motherboard located in the sealed volume.

The printed circuit board 452 can also be connected to via a connector 494 that is attached to a portion 496 of the printed circuit board 452 located outside of the enclosure 408. Although FIG. 4 illustrates one portion of the printed circuit board 452 extending outside of the sealed volume, in other embodiments more than one portion of no portions of the printed circuit board 452 extend outside of the sealed volume.

Although an enclosure with three portions is illustrated in FIG. 4, in other embodiments, an enclosure that encompasses integrated circuit components attached to a printed circuit board can comprise more or fewer than three portions. For example, the first portion 409 and the third portion 411 of the enclosure 408 could be combined in other embodiments. The presence of the third portion 411 allows for ease of access to the printed circuit board 452 and components attached to the printed circuit board 452, such as integrated circuit components 402 and 448 and connector 486. Ease of access to these components can be beneficial when a failed integrated circuit component needs replacing (due to, for example, failure, or the desire to install a different part) or other rework needs to be performed on the assembly. In some embodiments, an oleophobic coating can be added to the printed circuit board, integrated circuit components, and/or other components being protected from an immersion fluid before the components are immersed to protect the components from residual immersion fluid that may enter a sealed volume after a seal is opened. In some embodiments, additional secondary mechanical methods can be included in an assembly to protect components from exposure to immersion fluids, such as redundant seals, physical barriers designed to capture excess immersion fluid that might enter a sealed volume, or other suitable mechanical redundancies.

In any of the embodiments disclosed herein, an enclosure can comprise any material (e.g., a metal, a plastic) that is compatible with an immersion fluid to which the enclosure is exposed. An enclosure can comprise a single portion (e.g., 108, 208, 308) or multiple portions (e.g., enclosure 408 comprising portions 409, 410, and 411).

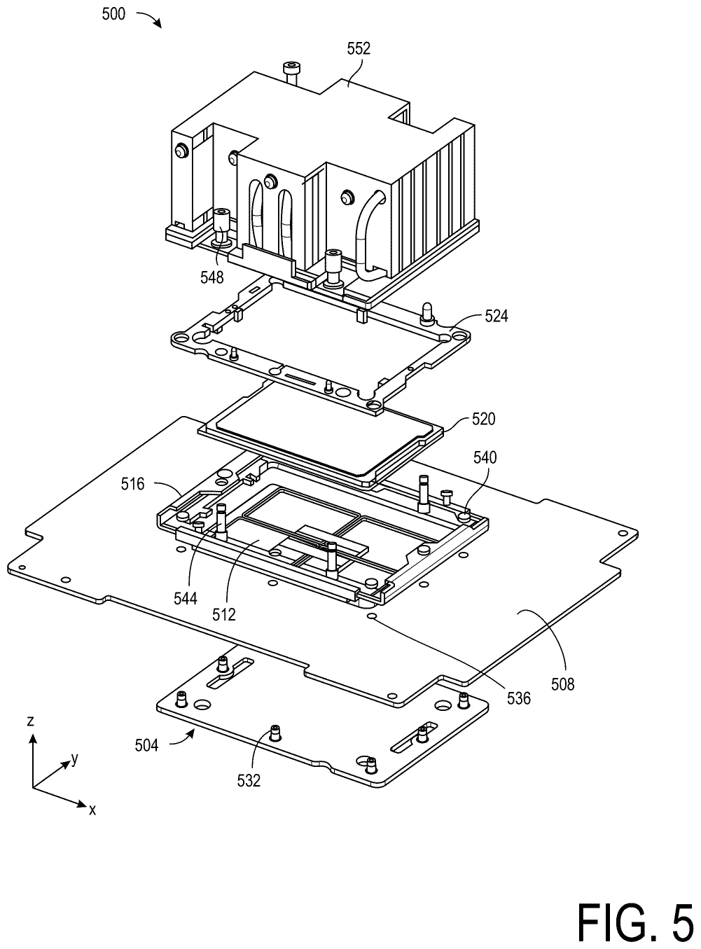

FIG. 5 illustrates an exploded perspective view of an example socketed processor apparatus. The apparatus 500 provides structural reliability to a processor stack (integrated circuit component and attached heat sink) and heat sink loading mechanism (the loading mechanism used to secure the heat sink to the socketed integrated circuit component). The apparatus 500 comprises a backplate 504, a printed circuit board 508, a socket 512, a bolster plate 516, an integrated circuit component 520, a carrier 524, and a heat sink 552.

The backplate 504 is attached to the printed circuit board 508 via fasteners 532 (e.g., studs) that extend through holes 536 in the printed circuit board 508 and attach to counterpart fasteners 540 of the bolster plate 516. The socket 512 is attached to the printed circuit board 508 and the integrated circuit component 520 is attached to the socket 512. The heat sink loading mechanism comprises attachment of the heat sink 552 to the bolster plate 516 via fasteners 544 (e.g., studs) that are part of the bolster plate 516 that extend through the carrier 524 and attach to counterpart fasteners 548 in the heat sink 528. The socket 512 can be any type of socket to which an integrated circuit component can attach, such as an LGA (land grid array), PGA (pin grid array) or BGA (ball grid array) socket. A layer of thermal interface material (not shown in FIG. 5) is located between the heat sink 528 and the integrated circuit component 520 to assist in the conduction of heat generated by the integrated circuit component 520 to the heat sink 528.

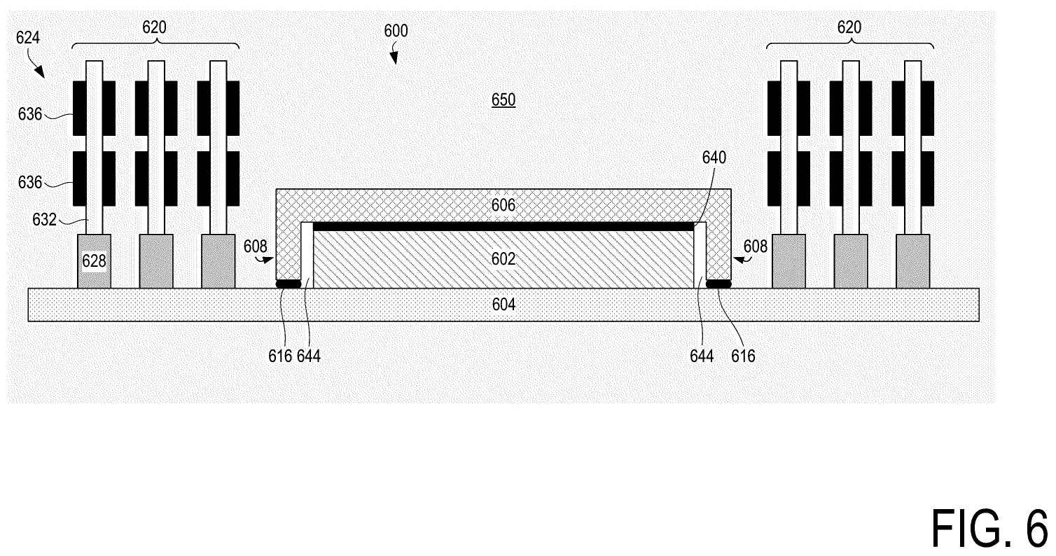

FIG. 6 is a cross-sectional view of a fifth example assembly for use in a liquid immersion cooling environment. The assembly 600 comprises an integrated circuit component 602 attached to a printed circuit board 604. The integrated circuit component 602 can be any processor described or referenced herein, or any other type of processor. The assembly 600 is shown as being located in a liquid immersion cooling environment and is surrounded by an immersion fluid 650. A heat sink 606 is located on integrated circuit component 602 with a layer 640 of thermal interface material positioned between the heat sink and the integrated circuit component 602. The heat sink 606 and the integrated circuit component 602 can be part of a socketed processor apparatus, such as apparatus 500.

The heat sink 606 comprises a ring 608 that encompasses the integrated circuit component 602 and extends the heat sink 606 in the direction of the printed circuit board 604. In other embodiments, the ring is a separate component from the heat sink and is attached to a bottom surface of the heat sink that overhangs the integrated circuit component. Regardless of whether the ring 608 is part of or is a separate component attached to the heat sink 606, the ring 608 is attached to the printed circuit board 604, thereby attaching the heat sink 606 to printed circuit board 604. The heat sink 606 and ring 608 can be attached to the printed circuit board 604 by fasteners (not shown).

The heat sink 606, the ring 608, and the printed circuit board 604 define a volume in which the integrated circuit component 602 is located. The attachment of the ring 608 to the printed circuit board 604 forms a seal between the ring 608 and the printed circuit board 604 that prevents immersion fluid 650 from entering the volume. Portions 644 of the sealed volume not occupied by components of the assembly 600 can be occupied by air. In the embodiment illustrated in FIG. 6, the seal between the heat sink 606 and the printed circuit board 604 comprises a gasket 616 that encompasses the base of the integrated circuit component 602 (where the integrated circuit component 602 attaches to the printed circuit board 604).

The assembly 600 further comprises banks 620 of memory modules 624 located on either side of the integrated circuit component 602. Each memory module 624 comprises memory integrated circuit components 636 attached to a printed circuit board 632 and a connector 628 that connects the module 624 to the printed circuit board 604. Each memory module 624 is electrically coupled to the integrated circuit component 602 by the printed circuit board 604.

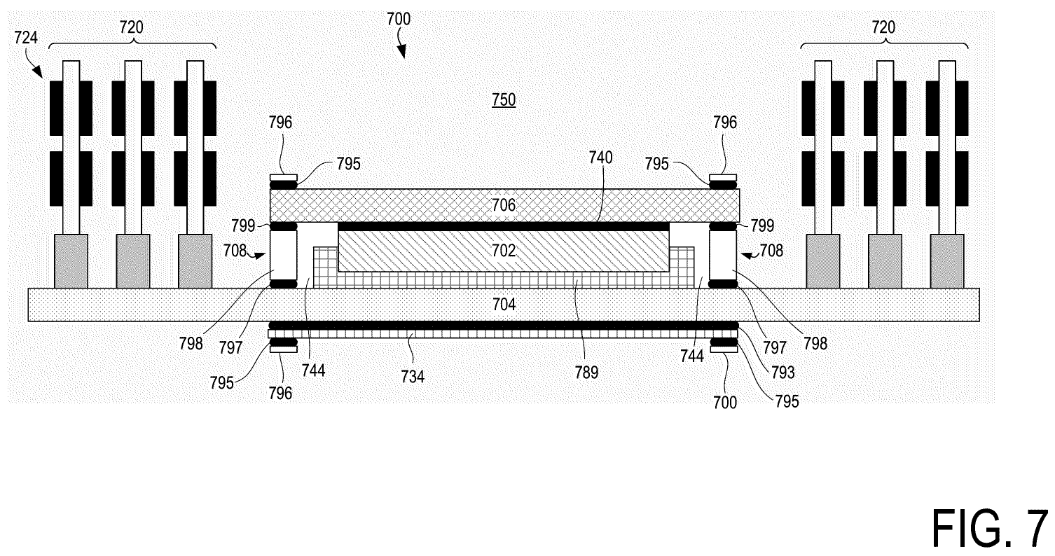

FIG. 7 is a cross-sectional view of a sixth example assembly for use in a liquid immersion cooling environment. The assembly 700 comprises a socket 789 attached to a printed circuit board 704 and an integrated circuit component 702 attached to the socket 789. The integrated circuit component 702 can be any processor described or referenced herein, or any other type of processor. The assembly 700 is located in a liquid immersion cooling environment and is surrounded by an immersion fluid 750. The assembly 700 further comprises a heat sink 706 that is located on the integrated circuit component 702 with a layer 740 of thermal interface material positioned between the heat sink 706 and the integrated circuit component 702.

A bolster plate (or plate) 798 is attached to the printed circuit board 704 via connection to a backplate 734 located on a bottom surface of the printed circuit board 704. The bolster plate 798 encompasses the integrated circuit component 702 and the socket 789. The bolster plate 798 comprises a ring 708 that encompasses the integrated circuit component 702 and the socket 789. The ring 708 extends the bolster plate 798 in a direction toward the heat sink 706. In other embodiments, the ring 708 is a separate component from the bolster plate 798 and is attached to the bolster plate 798. Regardless of whether the ring 708 is part of or is a separate component that attaches to the bolster plate 798, the ring 708 attaches to the heat sink 706 by fasteners 796 that extend through the backplate 734, the bolster plate 798, and the heat sink 706.

The heat sink 706, the bolster plate 798 (including the ring 708), and the printed circuit board 704 define a volume in which the integrated circuit component 702 and the socket 789 reside. The attachment of the ring 708 to the heat sink 706 forms a seal between the ring 708 and the heat sink 706 that prevents immersion fluid 750 from entering the volume. The portions 744 of the sealed volume not occupied by the components of the assembly 700 can be occupied by air. Attachment of the bolster plate 798 to the printed circuit board 704 also forms a seal that prevents immersion fluid from entering the sealed volume. The seal between the ring 708 and the heat sink 706, and the seal between the ring 708 and printed circuit board 704 comprise gaskets 799 and 797, respectively. The assembly 700 comprises several additional gaskets. Gaskets 795 are used in the attachment of the fasteners 796 to the heat sink 706 and backplate 734, and gasket 793 is used in the attachment of the bolster plate 798 to the bottom surface of the printed circuit board 704. The assembly 700 further comprises banks 720 of memory modules 724 located on either side of the integrated circuit component 702.

In a variation of the assembly 700 illustrated in FIG. 7, the ring that attaches to the heat sink to form a seal that isolates the integrated circuit component and socket from the immersion fluid encompasses the bolster plate as well as the socket and the integrated circuit component. In such embodiments, a top surface of the ring can attach to the heat sink and a bottom surface of the ring can attach to the printed circuit board, with gaskets between the ring and the heat sink and printed circuit board, respectively, to form seals that keep immersion fluid out of a volume defined by the ring, the printed circuit board, and the heat sink.

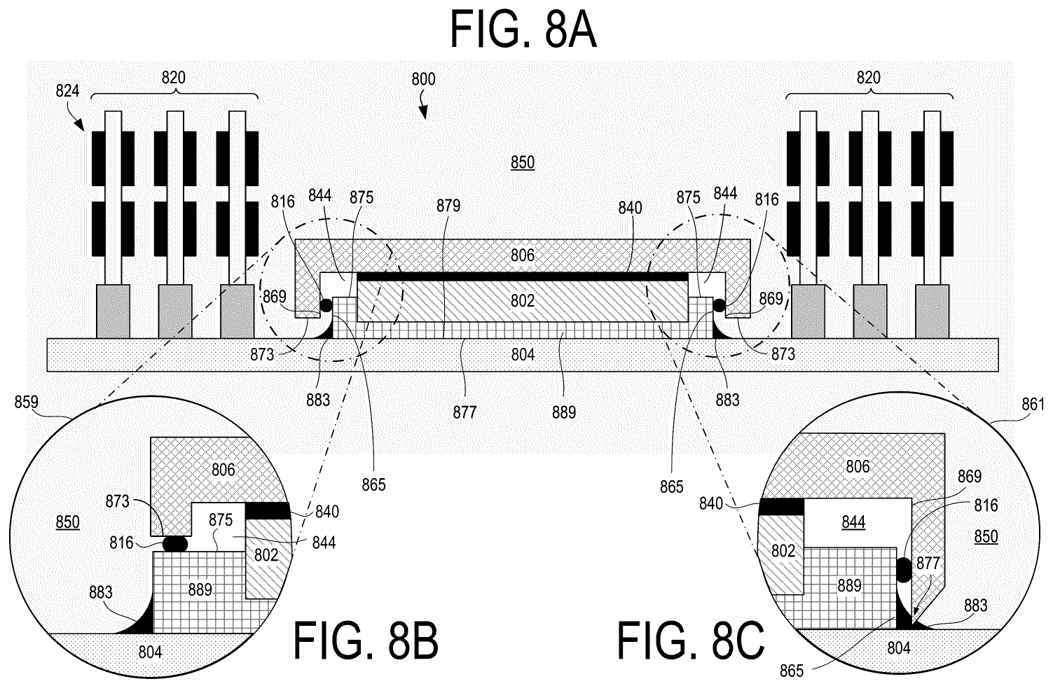

FIGS. 8A-8C are cross-sectional views of variations a seventh example assembly for use in a liquid immersion cooling environment. With reference to FIG. 8A, the assembly 800 comprises a socket 889 attached to a printed circuit board 804 and an integrated circuit component 802 attached to the socket 889. The integrated circuit component 802 can be any processor described or referenced herein, or any other type of processor. The assembly 800 is located in a liquid immersion cooling environment and is surrounded by an immersion fluid 850. The assembly 800 further comprises a heat sink 806 that is located on the integrated circuit component 802 with a layer 840 of thermal interface material positioned between the heat sink 806 and the integrated circuit component 802.

The heat sink 806 is attached to the printed circuit board 804 (although the attachments are not captured in the cross-section illustrated in FIG. 8A). Like the heat sink 606 of FIG. 6, the heat sink 806 has a “cap” shape with the edges of the cap overlapping the socket. That is, bottom surfaces 873 of the heat sink 806 overlap with top surfaces 875 of the socket 889. A seal is formed between inner surfaces 869 of the caps of the heat sink 806 and outer surfaces 865 of the socket 889 to prevent immersion fluid from entering a volume defined by the heat sink 806 and the socket 889. The seal can comprise a gasket 816. The portions 844 of the sealed volume not occupied by the components of the assembly 800 can be occupied by air. The heat sink 806 and the integrated circuit component 802 can be part of a socketed processor apparatus, such as apparatus 500.

The assembly 800 further comprises underfill material 883 that encompasses the perimeter of the base of the socket 889 (where the socket 889 meets the printed circuit board 804) and forms a seal between the socket 889 and the printed circuit board 804 to prevent immersion fluid from entering the volume between a bottom surface 879 of the socket 889 and a top surface 875 of the printed circuit board 804. The seal of underfill material 883 can thus protect the pin array connecting the socket 889 to the printed circuit board 804 from the immersion fluid 850. The underfill material 883 does not fill this volume between the socket 889 and the printed circuit board 804 but can do so in other embodiments. In other embodiments, a material different than the underfill material 833 can fill this volume. This different material may also be referred to as an underfill layer or material. The assembly 800 further comprises banks 820 of memory modules 824 located on either side of the integrated circuit component 802.

FIG. 8B illustrates a portion 859 of a first variation of the assembly 800 illustrated in FIG. 8A. In the first variation of the assembly 800, the bottom surfaces 873 of the heat sink 806 do not overlap but instead vertically align with the top surfaces 875 of the socket 889, and the gasket 816 is positioned between top surfaces 875 of the socket 889 and bottom surfaces 873 of the heat sink 806.

FIG. 8C illustrates a portion 861 of a second variation of the assembly 800 illustrated in FIG. 8A. In the second variation of the assembly 800, the heat sink 806 comprises an edge 877 that presses up against (or extends into) the underfill material 883, which is a compliant material, to create a seal that further isolates the integrated circuit component 802 and socket 889 from the immersion fluid 850. In some embodiments, there is no gasket 816 between the inner surface 869 of the heat sink 806 and the outer surface 865 of the socket 889, and the edge 877 pressing up against underfill material 883 isolates the integrated circuit component 802 and the socket 889 from the immersion fluid 850. Although the heat sink 806 is illustrated in FIG. 8C as having a triangular profile with an edge 877 that extends into the compressible underfill material, in other embodiments, the heat sink edge that extends into the underfill material 883 can be part of an end of a heat sink that has another profile, such as a rectangular profile or a rectangular profile with a bevel. Further, although the embodiments illustrated in FIGS. 8A-8C comprise the underfill material 883, in other embodiments, the underfill material 883 is absent. In any of the embodiments disclosed herein that comprises an underfill material that is exposed to immersion fluid, the underfill material is compatible with the immersion fluid the underfill material is to be exposed to. In embodiments where an integrated circuit component is attached to a socket, an additional seal can be formed between the integrated circuit component and the socket. This seal can be positioned the top, bottom, or side surfaces of a substrate of the integrated circuit component and the socket.

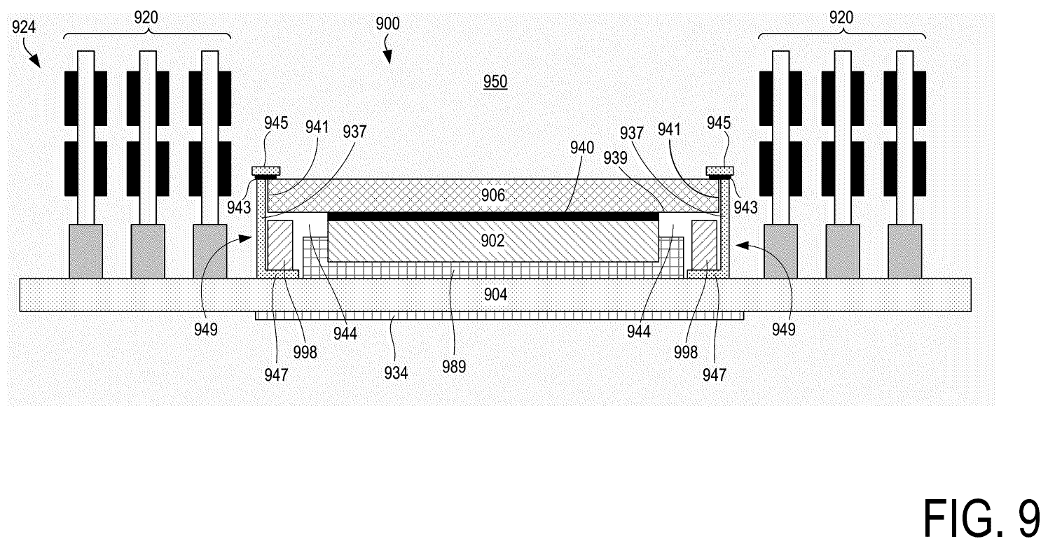

FIG. 9 is a cross-sectional view of an eighth example assembly for use in a liquid immersion cooling environment. The assembly 900 comprises a socket 989 attached to a printed circuit board 904 and an integrated circuit component 902 attached to the socket 989. The integrated circuit component 902 can be any processor described or referenced herein or any other type of processor. The assembly 900 is located in a liquid immersion cooling environment and is surrounded by an immersion fluid 950. The assembly 900 further comprises a heat sink 906 that is located on the integrated circuit component 902 with a layer 940 of thermal interface material positioned between the heat sink 906 and the integrated circuit component 902.

The assembly 900 further comprises a bolster plate 998 that is attached to the printed circuit board 904 via connection to a backplate 934 located on a back surface of the printed circuit board 904. The bolster plate 998 encompasses the integrated circuit component 902 and the socket 989. A ring 949 comprises a wall 937 that encompasses the bolster plate 998, the integrated circuit component 902, and the socket 989. The ring 949 further comprises a ledge 947 that is positioned between the bolster plate 998 and the printed circuit board 904. The ring 949 can be electrical insulating and is attached to the printed circuit board 904 and the heat sink 906. The ring 949 is attached to the heat sink 906 by a sealing cap (or cap) 945. The attachment of the ring 949 to the heat sink 906 via the sealing cap 945 forms a seal between the cap 945 and the heat sink 906 to prevent the immersion fluid from entering a volume defined by the heat sink 906, the ring 949, and the printed circuit board 904, with the integrated circuit component 902 and the socket 989 located in the volume. The seal comprises a gasket 943. The portions 944 of the sealed volume not occupied by the components of the assembly 900 can be occupied by air.

The ring 949 can comprise a rigid or a flexible material. If flexible, in some embodiments, the ring 949 does not require folding during assembly of the assembly 900 for the ring 949 to achieve its final shape before being attached to the heat sink 906. This can improve the case with which the ring 949 is installed in the assembly 900. The assembly 900 further comprises banks 920 of memory modules 924 located on either side of the integrated circuit component 902. In some embodiments, more or fewer memory modules 924 are attached to the printed circuit board 904. In other embodiments, one or more integrated circuit components or other electronic components can be attached to the printed circuit board 904 instead of or in addition to the memory modules 924.

Although FIG. 9 illustrates the ring 949 attached to a top surface of the heat sink 906 to form a seal to isolate the integrated circuit component 902 and the socket 989 from the immersion fluid 950, in other embodiments, the seal between the ring 949 and the heat sink 906 can be formed on a side surface (e.g., surface 941) or a bottom surface (e.g., surface 939) of the heat sink 906.

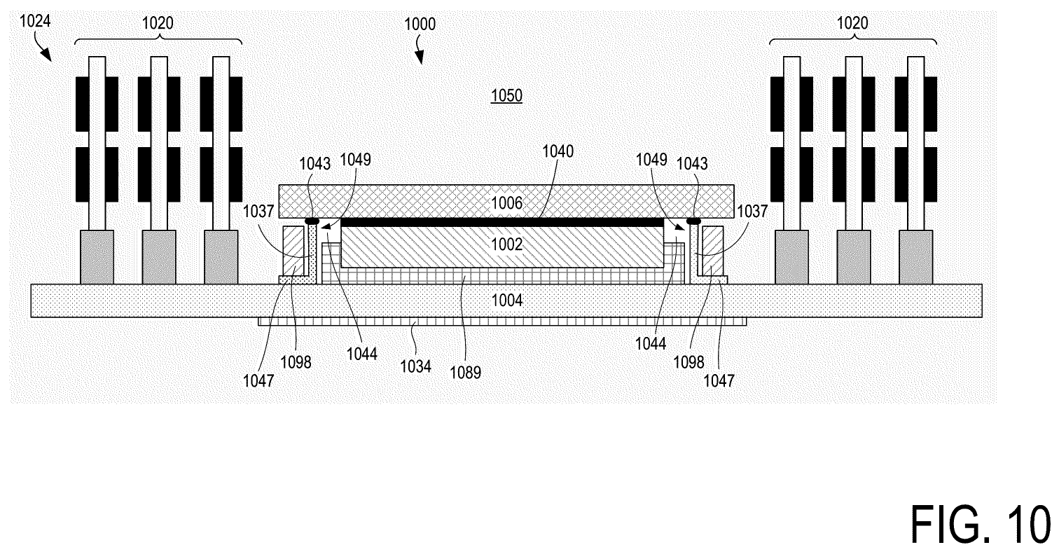

FIG. 10 is a cross-sectional view of a ninth example assembly for use in a liquid immersion cooling environment. The assembly 1000 is similar to the assembly 900, but with a ring 1049 located inside a bolster plate 1098 (instead of the ring encompassing the bolster plate). The assembly 1000 comprises a socket 1089 attached to a printed circuit board 1004 and an integrated circuit component 1002 attached to the socket 1089. The integrated circuit component 1002 can be any processor described or referenced herein or any other type of processor. The assembly 1000 is located in a liquid immersion cooling environment and is surrounded by an immersion fluid 1050. The assembly 1000 further comprises a heat sink 1006 that is located on the integrated circuit component 1002 with a layer 1040 of thermal interface material positioned between the heat sink 1006 and the integrated circuit component 1002.

The assembly 1000 further comprises a bolster plate 1098 that is attached to the printed circuit board 1004 via connection to a backplate 1034 located on a back surface of the printed circuit board 1004. The bolster plate 1098 encompasses the integrated circuit component 1002 and the socket 1089. A ring 1049 comprises a wall 1037 that encompasses the integrated circuit component 1002 and the socket 1089, with the wall 1037 being positioned between the bolster plate 1098 and the socket 1089. The ring 1049 further comprises a ledge 1047 positioned between the bolster plate 1098 and the printed circuit board 1004. The ring 1049 can be electrically insulating and is attached to the printed circuit board 1004. When the heat sink 1006 is loaded, a seal between the ring 1049 and the heat sink 1006 is formed to prevent the immersion fluid 1050 from entering a volume defined by the heat sink 1006, the ring 1049, and the printed circuit board 1004, with the integrated circuit component 1002 and the socket 1039 located in the volume. The positioning of the wall 1037 of the ring 1049 between the bolster plate 1098 and the socket 1089 exposes the bolster plate 1098 to the immersion fluid 1050. The seal comprises a gasket 1043. The portions 1044 of the sealed volume not occupied by the components of the assembly 1000 can be occupied by air.

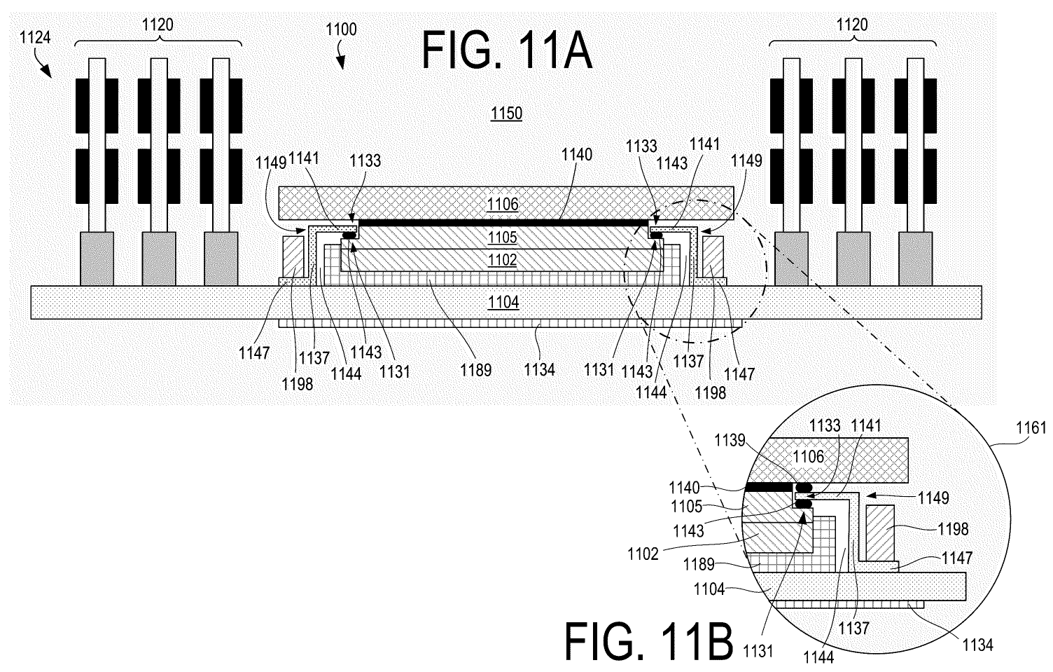

FIGS. 11A-11B are cross-sectional views of a tenth example assembly for use in a liquid immersion cooling environment. With reference to FIG. 11A, the assembly 1100 comprises a socket 1189 attached to a printed circuit board 1104 and an integrated circuit component 1102 attached to the socket 1189. An integrated heat spreader 1105 is located on the integrated circuit component 1102. The integrated circuit component 1102 can be any processor described or referenced herein or any other type of processor. The assembly 1100 is located in a liquid immersion cooling environment and is surrounded by an immersion fluid 1150. The assembly 1100 further comprises a heat sink 1106 that is located on the integrated heat spreader 1105 with a layer 1140 of thermal interface material positioned between the heat sink 1106 and the integrated heat spreader 1105. A layer of thermal interface material can be positioned between the integrated heat spreader 1005 and the integrated circuit component 1002 as well.

The assembly 1100 further comprises a bolster plate 1198 that is attached to the printed circuit board 1104 via connection to a backplate 1134 located on a back surface of the printed circuit board 1104. The bolster plate 1198 encompasses the integrated circuit component 1102 and the socket 1189. A ring 1149 comprises a wall 1137 that encompasses the integrated circuit component 1102 and the socket 1189, with the wall 1137 being positioned between the bolster plate 1198 and the socket 1189. The ring 1149 further comprises a bottom ledge 1147 positioned between the bolster plate 1198 and the printed circuit board 1104. The ring 1190 also comprises a top ledge 1141, an end 1133 of which is located between a shoulder 1131 of the integrated heat spreader 1105 and the heat sink 1106. The ring 1149 can be electrical insulating and is attached to the printed circuit board 1104. A seal between the top ledge 1141 of the ring 1149 and the shoulder 1131 of the integrated heat spreader 1105 prevents the immersion fluid 1150 from entering a volume defined by the ring 1149, the integrated heat spreader 1105, and the printed circuit board 1104, with the integrated circuit component 1102 and the socket 1189 located in the volume. The seal comprises a gasket 1143. The portions 1144 of the sealed volume not occupied by the components of the assembly 1100 can be occupied by air. The layer 1040 of thermal interface material is exposed to the immersion fluid 1050.

FIG. 11B illustrates a portion 1161 of a variation of the assembly 1100 illustrated in FIG. 11A. In the variation of the assembly 1100, a second seal is positioned between the end 1133 of the top ledge 1141 of the ring 1149 and the heat sink 1106. This second seal further prevents immersion liquid from entering the volume sealed by the seal positioned between the top ledge 1141 of the ring 1149 and the integrated heat spreader 1105, as well as isolating the layer 1140 of thermal interface material from the immersion liquid 1150. The second seal comprises a gasket 1139.

The assemblies 900, 1100, and 1100 comprise banks (920, 1120, 1120) of memory modules (924, 1124, 1124) located on either side of the integrated circuit component (902, 1102, 1102). In some embodiments, more or fewer memory modules are attached to the printed circuit board (9006, 1106, 1106) than what is illustrated in FIGS. 9, 10, and 11A-11B. In other embodiments, one or more integrated circuit components or other electronic components can be attached to the printed circuit board instead of or in addition to the memory modules.

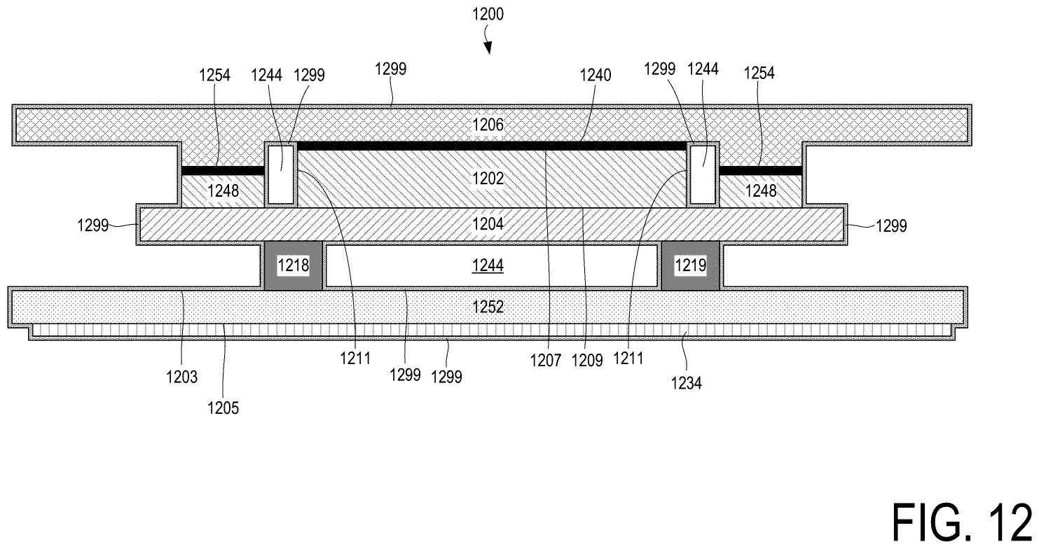

FIG. 12 is a cross-sectional view of an eleventh example assembly for use in a liquid immersion cooling environment. The assembly 1200 is similar to the assembly 100, but with a conformal coating 1299 on the external surfaces of the assembly (assembly external surfaces). The coating 1299 can be: (1) hydrophobic or super-hydrophobic as well as oleophobic or super-oleophobic; (2) amphiphobic or super-amphiphobic; (3) omniphobic; or (4) any combination of (1), (2), and (3). The coating 1299 acts as a physical and/or chemical reaction barrier that prevents computing components from being exposed to immersion fluids. The assembly external surfaces are the surfaces of the components forming the assembly 1200 (integrated circuit component 1202, printed circuit boards 1204 and 1252, connectors 1218 and 1219, heat sink 1206, backplate 1234) that are exposed to the environment and that would be exposed to an immersion fluid if the assembly 1200 were submerged in the immersion fluid and the coating 1299 was absent. The assembly external surfaces include outward-facing surfaces (e.g., the top surface of the heat sink 1206, the bottom surface of the backplate 1234) and inward-facing surfaces (e.g., component surfaces that face volumes 1244) of the assembly 1200. The coating is conformal in that its shape matches that of the assembly external surfaces. While the coating 1299 in FIG. 12 is shown as having a uniform thickness, the thickness of the coating can vary over the external surfaces of the assembly. In some embodiments, the thickness of the coating can be in a range of about one micron to 50 microns. The conformal coating can meet IPX7 and IPX8 ingress protection (IP) codes defined by the International Electrotechnical Commission (IEC) under IEC standard 60529.

In some embodiments, the conformal coating 1299 can be a fluorinated coating that is hydrophobic or super-hydrophobic as well as oleophobic or super-oleophobic. Processes that are capable of generating these coatings include physical vapor deposition, chemical vapor deposition, liquid vapor deposition, electrochemical techniques, the use of film coating equipment, spraying, high-speed jetting, the use of dispense equipment, dip coating, sputtering, and/or combinations thereof. Due to their inertness, there is little to no chemical interaction between these coatings and assembly component materials.

In other embodiments, the conformal coating 1299 can be a parylene coating. The parylene coating can be formed via chemical vapor deposition. These coatings can be applied on a wide variety of surface topographies and are capable of penetrating small surface crevices. These coatings can provide protection from contaminants, corrosion, chemicals, gases, and moisture and have high thermal stability.

In still other embodiments, the conformal coating 1299 can be a super-amphiphobic coating. These coatings can be applied by spraying a fluorinated resin coat comprising nanoparticles (particles having a length of 1-100 nm in at least one dimension) comprising inorganic silicon dioxide (SiO₂), titanium dioxide (TiO₂), copper (ii) oxide (or cupric oxide, CuO), zinc oxide (ZnO), calcium carbonate (CaCO₃), aluminum oxide (Al₂O₃), magnesium oxide (MgO), carbon-based nanoparticles (e.g., fullerene or carbon nanotubes), nanoclay (e.g., montmorillonite clay ((Na, Ca)_{0.33}(Al, Mg)₂Si₄O₁₀(OH)₂·nH₂O)) nanoparticles, or any combination thereof having high degrees of fluoro-densification. These coatings possess super liquid-repellency and prolonged oil-immersion capability.

In yet other embodiments, the conformal coating 1299 can comprise a non-fluorobased non-oleophobic polymeric coating, such as polyurethane, epoxy, or polyimide that functions to encapsulate assembly components from immersion fluids.

The hydrophobic, super-hydrophobic, oleophobic, super-oleophobic, amphiphobic, super-amphiphobic, and/or omniphobic properties of a coating can be detected on external surfaces of an assembly as follows. A water contact angle of greater than about 90 degrees indicates the presence of a hydrophobic coating. A water contact angle of greater than about 150 degrees indicates the presence of a super-hydrophobic coating. Oleophobic coatings have a water contact angle in the range of about 105 degrees to about 120 degrees and a contact angle of a probe liquid droplet of a short-chain alkane, such as n-decane, n-dodecane, n-hexadecane, diiodomethane, etc. of greater than about 60 degrees on a solid surface. The contact angle of a probe liquid droplet of a short-chain alkane of greater than about 150 degrees indicates the presence of a super-oleophobic layer. An amphiphobic coating (a coating that exhibits both hydrophobic and oleophobic properties) can be indicated by a coating having both water and oil contact angles of greater than about 90 degrees, while a super-amphiphobic coating (a coating that exhibits both super-hydrophobic and super-oleophobic properties) can be indicated by a coating having a probe liquid contact angle of greater than about 150 degrees. An omniphobic coating repels almost all fluids, in particular liquids having very low surface tension, such as in the range of about 10 to about 50 mN/m. To detect the presence of a fluoropolymer-based coating, SEM-EDX (scanning electron microscopy-energy-dispersive x-ray spectroscopy) imaging of the motherboard would detect the presence of non-polar groups such as fluorine, chlorine, etc.

Although the coating 1299 is shown as covering all assembly external surfaces of the assembly 1200, in other embodiments, fewer than all the assembly external surfaces can be coated. For example, a conformal coating could cover the assembly external surfaces for select components forming an assembly. That is, in some embodiments, assembly external surfaces that are part of connectors or a backplate may not be coated. In other examples, fewer than all the assembly external surfaces of an individual assembly component are coated. For example, only portions of the top assembly external surface (e.g., surface 1203) of a motherboard or portions of the bottom assembly external surface (e.g., 1205) of a backplate may be coated. Further, any of the conformal coatings described herein can be on all of the external surfaces of any of the individual components forming an assembly. For example, in some embodiments, the top, bottom, and side surfaces 1207, 1209, and 1211 of integrated circuit component 1202 can be covered by a conformal coating. In other embodiments, fewer than all of the external surfaces of one or more individual components of an assembly are coated.

Although FIG. 12 illustrates a conformal coating on the external surfaces of an assembly 1200 that is similar to assembly 100 illustrated in FIG. 12, any assembly or any components that are part of an assembly described herein can comprise any of the conformal coatings described herein.

The immersion fluid isolation and protection technologies disclosed herein can be utilized with any type of immersion fluid, such as synthetic hydrocarbons, gas-to-liquid fluids or iso-paraffins, mineral oils, silicone oils, bio-based fluids and fluorinated liquids.

Any of the gaskets described herein are compliant such that when a gasket is compressed in response to a load being applied to a component adjacent to the gasket (such as a load applied to a heat sink), it prevents immersion fluid from passing through a seal comprising the gasket. The gasket can be made of a suitable material that is compatible with an immersion fluid in which the gasket is to be immersed or submerged.

Any of the seals described herein can be made in fashions other than positioning a compressible gasket between two components. In some embodiments, a seal may be formed by having two flat surfaces with hydrophobic, oleophobic, amphiphobic, and/or omniphobic coatings touch each other. In other embodiments, a seal can comprise B-staged epoxy, UV (ultraviolet) curable epoxy, polyimide, liquid crystalline polymers, PEEK (polyether ether ketone), or PPS (polyphenylene sulfide).

Although some of the Figures do not illustrate a backplate, in embodiments other than those illustrated, a backplate can be used in the attachment of an assembly to a printed circuit board. Similarly, embodiments illustrated as having a backplate may not have a backplate in other embodiments.

Any of the fasteners described herein can comprise a screw, bolt, nut, standoff (e.g., threaded, snap-on), rivet, stud, pin (e.g., snap-fit, press-fit), or another suitable fastener.

Any of the layers of thermal interface material described herein can comprise any suitable thermally conductive material, such as a silver thermal compound, thermal grease, phase change materials, indium foils, graphite sheets, or graphene sheets.

The immersion fluid isolation technologies described herein can be used to isolate a printed circuit board and components located thereon from immersion fluids. In addition to various types of integrated circuit components, such as processors (e.g., CPUs, GPUS, NPUs) and memories, the technologies disclosed herein can isolate components such as power supplies, voltage regulators, batteries, and antennas from immersion fluids.

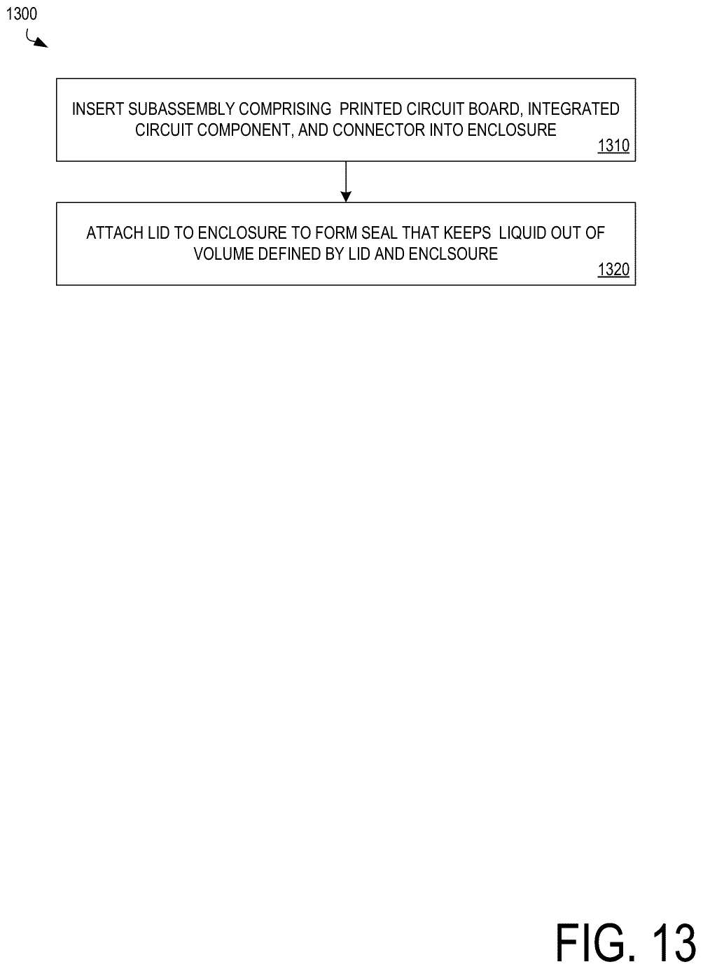

FIG. 13 is an example method of protecting and/or isolating components from immersion fluids. The method 1300 can be performed by, for example, a server manufacturer. At 1310, a subassembly is inserted into an enclosure, the subassembly comprising a printed circuit board, an integrated circuit component, and a connector, wherein the printed circuit board and the connector are attached to the printed circuit board, and a portion of the connector extends through an opening in the enclosure. At 1320, a lid is attached to the enclosure, the lid and the enclosure defining a volume within which the integrated circuit component and the printed circuit board are located, wherein the attachment of the lid to the enclosure forms a seal to keep liquid out of the volume. In other embodiments, the method 1300 can comprise one or more additional elements. For example, the method 1300 can further comprise, attaching the lid to a second printed circuit board. In another example, the method 1300 can further comprise, inserting the subassembly, lid, and enclosure into a tank at least partially filled with liquid, wherein the subassembly, the lid, and the enclosure are submerged in the liquid.

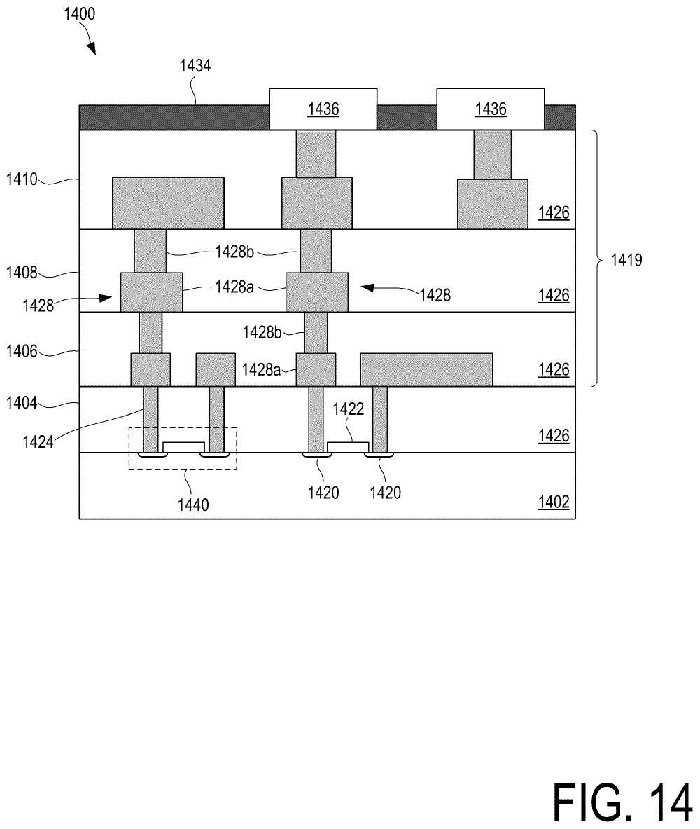

FIG. 14 is a cross-sectional view of an integrated circuit die 1400 that may be included in any of the integrated circuit components disclosed herein. The integrated circuit device 1400 may be formed on a die substrate 1402. The die substrate 1402 may be a semiconductor substrate composed of semiconductor material systems including, for example, n-type or p-type materials systems (or a combination of both). The die substrate 1402 may include, for example, a crystalline substrate formed using a bulk silicon or a silicon-on-insulator (SOI) substructure. In some embodiments, the die substrate 1402 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 1402. Although a few examples of materials from which the die substrate 1402 may be formed are described here, any material that may serve as a foundation for an integrated circuit device 1400 may be used.

The integrated circuit device 1400 may include one or more device layers 1404 disposed on the die substrate 1402. The device layer 1404 may include features of one or more transistors 1440 (e.g., metal oxide semiconductor field-effect transistors (MOSFETs)) formed on the die substrate 1402. The transistors 1440 may include, for example, one or more source and/or drain (S/D) regions 1420, a gate 1422 to control current flow between the S/D regions 1420, and one or more S/D contacts 1424 to route electrical signals to/from the S/D regions 1420. The transistors 1440 may include additional features not depicted for the sake of clarity, such as device isolation regions, gate contacts, and the like. The transistors 1440 are not limited to the type and configuration depicted in FIG. 14 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon, nanosheet, or nanowire transistors.

Returning to FIG. 14, a transistor 1440 may include a gate 1422 formed of at least two layers, a gate dielectric, and a gate electrode. The gate dielectric may include one layer or a stack of layers. The one or more layers may include silicon oxide, silicon dioxide, silicon carbide, and/or a high-k dielectric material.

The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 1440 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 1440 along the source-channel-drain direction, the gate electrode may consist of a U-shaped structure that includes a bottom portion substantially parallel to the surface of the die substrate 1402 and two sidewall portions that are substantially perpendicular to the top surface of the die substrate 1402. In other embodiments, at least one of the metal layers that form the gate electrode may simply be a planar layer that is substantially parallel to the top surface of the die substrate 1402 and does not include sidewall portions substantially perpendicular to the top surface of the die substrate 1402. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 1420 may be formed within the die substrate 1402 adjacent to the gate 1422 of individual transistors 1440. The S/D regions 1420 may be formed using an implantation/diffusion process or an etching/deposition process, for example. In the former process, dopants such as boron, aluminum, antimony, phosphorous, or arsenic may be ion-implanted into the die substrate 1402 to form the S/D regions 1420. An annealing process that activates the dopants and causes them to diffuse farther into the die substrate 1402 may follow the ion-implantation process. In the latter process, the die substrate 1402 may first be etched to form recesses at the locations of the S/D regions 1420. An epitaxial deposition process may then be carried out to fill the recesses with material that is used to fabricate the S/D regions 1420. In some implementations, the S/D regions 1420 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 1420 may be formed using one or more alternate semiconductor materials such as germanium or a group III-V material or alloy. In further embodiments, one or more layers of metal and/or metal alloys may be used to form the S/D regions 1420.

Electrical signals, such as power and/or input/output (I/O) signals, may be routed to and/or from the devices (e.g., transistors 1440) of the device layer 1404 through one or more interconnect layers disposed on the device layer 1404 (illustrated in FIG. 14 as interconnect layers 1406-1410). For example, electrically conductive features of the device layer 1404 (e.g., the gate 1422 and the S/D contacts 1424) may be electrically coupled with the interconnect structures 1428 of the interconnect layers 1406-1410. The one or more interconnect layers 1406-1410 may form a metallization stack (also referred to as an “ILD stack”) 1419 of the integrated circuit device 1400.

The interconnect structures 1428 may be arranged within the interconnect layers 1406-1410 to route electrical signals according to a wide variety of designs; in particular, the arrangement is not limited to the particular configuration of interconnect structures 1428 depicted in FIG. 14. Although a particular number of interconnect layers 1406-1410 is depicted in FIG. 14, embodiments of the present disclosure include integrated circuit devices having more or fewer interconnect layers than depicted.

In some embodiments, the interconnect structures 1428 may include lines 1428a and/or vias 1428b filled with an electrically conductive material such as a metal. The lines 1428a may be arranged to route electrical signals in a direction of a plane that is substantially parallel with a surface of the die substrate 1402 upon which the device layer 1404 is formed. For example, the lines 1428a may route electrical signals in a direction in and out of the page and/or in a direction across the page from the perspective of FIG. 14. The vias 1428b may be arranged to route electrical signals in a direction of a plane that is substantially perpendicular to the surface of the die substrate 1402 upon which the device layer 1404 is formed. In some embodiments, the vias 1428b may electrically couple lines 1428a of different interconnect layers 1406-1410 together.

The interconnect layers 1406-1410 may include a dielectric material 1426 disposed between the interconnect structures 1428, as shown in FIG. 14. In some embodiments, dielectric material 1426 disposed between the interconnect structures 1428 in different ones of the interconnect layers 1406-1410 may have different compositions; in other embodiments, the composition of the dielectric material 1426 between different interconnect layers 1406-1410 may be the same. The device layer 1404 may include a dielectric material 1426 disposed between the transistors 1440 and a bottom layer of the metallization stack as well. The dielectric material 1426 included in the device layer 1404 may have a different composition than the dielectric material 1426 included in the interconnect layers 1406-1410; in other embodiments, the composition of the dielectric material 1426 in the device layer 1404 may be the same as a dielectric material 1426 included in any one of the interconnect layers 1406-1410.

A first interconnect layer 1406 (referred to as Metal 1 or “M1”) may be formed directly on the device layer 1404. In some embodiments, the first interconnect layer 1406 may include lines 1428a and/or vias 1428b, as shown. The lines 1428a of the first interconnect layer 1406 may be coupled with contacts (e.g., the S/D contacts 1424) of the device layer 1404. The vias 1428b of the first interconnect layer 1406 may be coupled with the lines 1428a of a second interconnect layer 1408.

The second interconnect layer 1408 (referred to as Metal 2 or “M2”) may be formed directly on the first interconnect layer 1406. In some embodiments, the second interconnect layer 1408 may include via 1428b to couple the lines 1428 of the second interconnect layer 1408 with the lines 1428a of a third interconnect layer 1410. Although the lines 1428a and the vias 1428b are structurally delineated with a line within individual interconnect layers for the sake of clarity, the lines 1428a and the vias 1428b may be structurally and/or materially contiguous (e.g., simultaneously filled during a dual-damascene process) in some embodiments.

The third interconnect layer 1410 (referred to as Metal 3 or “M3”) (and additional interconnect layers, as desired) may be formed in succession on the second interconnect layer 1408 according to similar techniques and configurations described in connection with the second interconnect layer 1408 or the first interconnect layer 1406. In some embodiments, the interconnect layers that are “higher up” in the metallization stack 1419 in the integrated circuit device 1400 (i.e., farther away from the device layer 1404) may be thicker than the interconnect layers that are lower in the metallization stack 1419, with lines 1428a and vias 1428b in the higher interconnect layers being thicker than those in the lower interconnect layers.

The integrated circuit device 1400 may include a solder resist material 1434 (e.g., polyimide or similar material) and one or more conductive contacts 1436 formed on the interconnect layers 1406-1410. In FIG. 14, the conductive contacts 1436 are illustrated as taking the form of bond pads. The conductive contacts 1436 may be electrically coupled with the interconnect structures 1428 and configured to route the electrical signals of the transistor(s) 1440 to external devices. For example, solder bonds may be formed on the one or more conductive contacts 1436 to mechanically and/or electrically couple an integrated circuit die including the integrated circuit device 1400 with another component (e.g., a printed circuit board). The integrated circuit device 1400 may include additional or alternate structures to route the electrical signals from the interconnect layers 1406-1410; for example, the conductive contacts 1436 may include other analogous features (e.g., posts) that route the electrical signals to external components.

In some embodiments in which the integrated circuit device 1400 is a double-sided die, the integrated circuit device 1400 may include another metallization stack (not shown) on the opposite side of the device layer(s) 1404. This metallization stack may include multiple interconnect layers as discussed above with reference to the interconnect layers 1406-1410, to provide conductive pathways (e.g., including conductive lines and vias) between the device layer(s) 1404 and additional conductive contacts (not shown) on the opposite side of the integrated circuit device 1400 from the conductive contacts 1436.

In other embodiments in which the integrated circuit device 1400 is a double-sided die, the integrated circuit device 1400 may include one or more through silicon vias (TSVs) through the die substrate 1402; these TSVs may make contact with the device layer(s) 1404, and may provide conductive pathways between the device layer(s) 1404 and additional conductive contacts (not shown) on the opposite side of the integrated circuit device 1400 from the conductive contacts 1436. In some embodiments, TSVs extending through the substrate can be used for routing power and ground signals from conductive contacts on the opposite side of the integrated circuit device 1400 from the conductive contacts 1436 to the transistors 1440 and any other components integrated into the die 1400, and the metallization stack 1419 can be used to route I/O signals from the conductive contacts 1436 to transistors 1440 and any other components integrated into the die 1400.

Multiple integrated circuit devices 1400 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

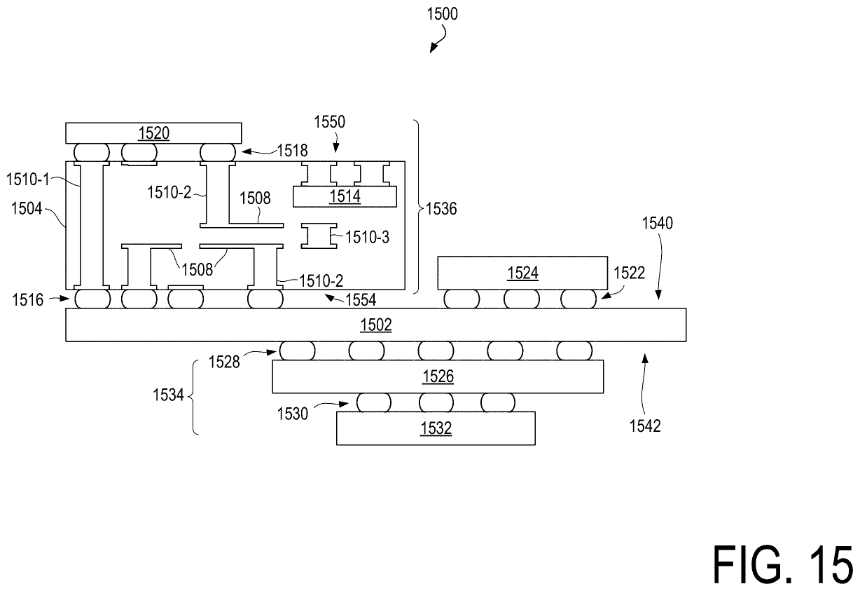

FIG. 15 is a cross-sectional side view of an integrated circuit device assembly 1500 that may include any of the assemblies (e.g., 100, 200, 1200) disclosed herein. The integrated circuit device assembly 1500 includes a number of components disposed on a printed circuit board 1502 (which may be a motherboard, system board, mainboard, etc.). The integrated circuit device assembly 1500 includes components disposed on a first face 1540 of the circuit board 1502 and an opposing second face 1542 of the circuit board 1502; generally, components may be disposed on one or both faces 1540 and 1542.

In some embodiments, the circuit board 1502 may be a printed circuit board (PCB) including multiple metal (or interconnect) layers separated from one another by layers of dielectric material (e.g., FR-4 or other fiberglass-reinforced epoxy laminate) and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 1502. In other embodiments, the circuit board 1502 may be a non-PCB substrate. In some embodiments the circuit board 1502 may be, for example, the circuit board 152. The integrated circuit device assembly 1500 illustrated in FIG. 15 includes a package-on-interposer structure 1536 coupled to the first face 1540 of the circuit board 1502 by coupling components 1516. The coupling components 1516 may electrically and mechanically couple the package-on-interposer structure 1536 to the circuit board 1502, and may include solder balls (as shown in FIG. 15), pins (e.g., as part of a pin grid array (PGA), contacts (e.g., as part of a land grid array (LGA)), male and female portions of a socket, an adhesive, an underfill material, and/or any other suitable electrical and/or mechanical coupling structure. The coupling components 1516 may serve as the coupling components illustrated or described for any of the substrate assembly or substrate assembly components described herein, as appropriate.

The package-on-interposer structure 1536 may include an integrated circuit component 1520 coupled to an interposer 1504 by coupling components 1518. The coupling components 1518 may take any suitable form for the application, such as the forms discussed above with reference to the coupling components 1516. Although a single integrated circuit component 1520 is shown in FIG. 15, multiple integrated circuit components may be coupled to the interposer 1504; indeed, additional interposers may be coupled to the interposer 1504. The interposer 1504 may provide an intervening substrate used to bridge the circuit board 1502 and the integrated circuit component 1520.

The integrated circuit component 1520 may be a packaged or unpacked integrated circuit product that includes one or more integrated circuits, the integrated circuit device 1400 of FIG. 14) and/or one or more other suitable components. A packaged integrated circuit component comprises one or more integrated circuit dies mounted on a package substrate with the integrated circuit dies and package substrate encapsulated in a casing material, such as a metal, plastic, glass, or ceramic. In one example of an unpackaged integrated circuit component 1520, a single monolithic integrated circuit die comprises solder bumps attached to contacts on the die. The solder bumps allow the die to be directly attached to the interposer 1504. The integrated circuit component 1520 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the integrated circuit component 1520 can comprise one or more additional active or passive devices such as capacitors, decoupling capacitors, resistors, inductors, fuses, diodes, transformers, sensors, electrostatic discharge (ESD) devices, and memory devices.

In embodiments where the integrated circuit component 1520 comprises multiple integrated circuit dies, the dies can be the same type (a homogeneous multi-die integrated circuit component) or two or more different types (a heterogeneous multi-die integrated circuit component). A multi-die integrated circuit component can be referred to as a multi-chip package (MCP) or multi-chip module (MCM).

In addition to comprising one or more processor units, the integrated circuit component 1520 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Generally, the interposer 1504 may spread connections to a wider pitch or reroute a connection to a different connection. For example, the interposer 1504 may couple the integrated circuit component 1520 to a set of ball grid array (BGA) conductive contacts of the coupling components 1516 for coupling to the circuit board 1502. In the embodiment illustrated in FIG. 15, the integrated circuit component 1520 and the circuit board 1502 are attached to opposing sides of the interposer 1504; in other embodiments, the integrated circuit component 1520 and the circuit board 1502 may be attached to a same side of the interposer 1504. In some embodiments, three or more components may be interconnected by way of the interposer 1504.

In some embodiments, the interposer 1504 may be formed as a PCB, including multiple metal layers separated from one another by layers of dielectric material and interconnected by electrically conductive vias. In some embodiments, the interposer 1504 may be formed of an epoxy resin, a fiberglass-reinforced epoxy resin, an epoxy resin with inorganic fillers, a ceramic material, or a polymer material such as polyimide. In some embodiments, the interposer 1504 may be formed of alternate rigid or flexible materials that may include the same materials described above for use in a semiconductor substrate, such as silicon, germanium, and other group III-V and group IV materials. The interposer 1504 may include metal interconnects 1508 and vias 1510, including but not limited to through hole vias 1510-1 (that extend from a first face 1550 of the interposer 1504 to a second face 1554 of the interposer 1504), blind vias 1510-2 (that extend from the first or second faces 1550 or 1554 of the interposer 1504 to an internal metal layer), and buried vias 1510-3 (that connect internal metal layers).

In some embodiments, the interposer 1504 can comprise a silicon interposer. Through silicon vias (TSV) extending through the silicon interposer can connect connections on a first face of a silicon interposer to an opposing second face of the silicon interposer. In some embodiments, an interposer 1504 comprising a silicon interposer can further comprise one or more routing layers to route connections on a first face of the interposer 1504 to an opposing second face of the interposer 1504.

The interposer 1504 may further include embedded devices 1514, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1504. The package-on-interposer structure 1536 may take the form of any of the package-on-interposer structures known in the art. In embodiments where the interposer is a non-printed circuit board

The integrated circuit device assembly 1500 may include an integrated circuit component 1524 coupled to the first face 1540 of the circuit board 1502 by coupling components 1522. The coupling components 1522 may take the form of any of the embodiments discussed above with reference to the coupling components 1516, and the integrated circuit component 1524 may take the form of any of the embodiments discussed above with reference to the integrated circuit component 1520.

The integrated circuit device assembly 1500 illustrated in FIG. 15 includes a package-on-package structure 1534 coupled to the second face 1542 of the circuit board 1502 by coupling components 1528. The package-on-package structure 1534 may include an integrated circuit component 1526 and an integrated circuit component 1532 coupled together by coupling components 1530 such that the integrated circuit component 1526 is disposed between the circuit board 1502 and the integrated circuit component 1532. The coupling components 1528 and 1530 may take the form of any of the embodiments of the coupling components 1516 discussed above, and the integrated circuit components 1526 and 1532 may take the form of any of the embodiments of the integrated circuit component 1520 discussed above. The package-on-package structure 1534 may be configured in accordance with any of the package-on-package structures known in the art.

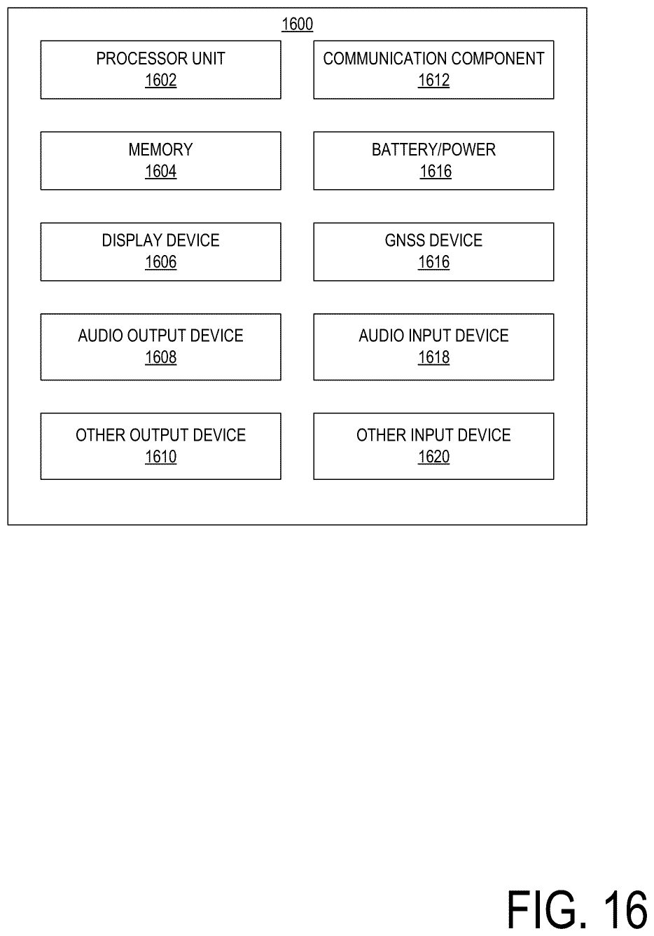

FIG. 16 is a block diagram of an example electrical device 1600 that may include one or more of the integrated circuit component assemblies (e.g., 100, 200, 1200) disclosed herein. For example, any suitable ones of the components of the electrical device 1600 may include one or more of the assemblies 1500, integrated circuit components 1520, integrated circuit dies 1400 disclosed herein, and may be arranged in any of the assemblies 100 disclosed herein. A number of components are illustrated in FIG. 16 as included in the electrical device 1600, but any one or more of these components may be omitted or duplicated, as suitable for the application. In some embodiments, some or all the components included in the electrical device 1600 may be attached to one or more motherboards mainboards, or system boards. In some embodiments, one or more of these components are fabricated onto a single system-on-a-chip (SoC) die.

Additionally, in various embodiments, the electrical device 1600 may not include one or more of the components illustrated in FIG. 16, but the electrical device 1600 may include interface circuitry for coupling to the one or more components. For example, the electrical device 1600 may not include a display device 1606, but may include display device interface circuitry (e.g., a connector and driver circuitry) to which a display device 1606 may be coupled. In another set of examples, the electrical device 1600 may not include an audio input device 1624 or an audio output device 1608, but may include audio input or output device interface circuitry (e.g., connectors and supporting circuitry) to which an audio input device 1624 or audio output device 1608 may be coupled.

The electrical device 1600 may include one or more processor units 1602 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 1602 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 1600 may include a memory 1604, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 1604 may include memory that is located on the same integrated circuit die as the processor unit 1602. This memory may be used as cache memory (e.g., Level 1 (L1), Level 2 (L2), Level 3 (L3), Level 4 (L4), Last Level Cache (LLC)) and may include embedded dynamic random-access memory (eDRAM) or spin transfer torque magnetic random-access memory (STT-MRAM).

In some embodiments, the electrical device 1600 can comprise one or more processor units 1602 that are heterogeneous or asymmetric to another processor unit 1602 in the electrical device 1600. There can be a variety of differences between the processing units 1602 in a system in terms of a spectrum of metrics of merit including architectural, microarchitectural, thermal, power consumption characteristics, and the like. These differences can effectively manifest themselves as asymmetry and heterogeneity among the processor units 1602 in the electrical device 1600.

In some embodiments, the electrical device 1600 may include a communication component 1612 (e.g., one or more communication components). For example, the communication component 1612 can manage wireless communications for the transfer of data to and from the electrical device 1600. The term “wireless” and its derivatives may be used to describe circuits, devices, systems, methods, techniques, communications channels, etc., that may communicate data using modulated electromagnetic radiation through a nonsolid medium. The term “wireless” does not imply that the associated devices do not contain any wires, although in some embodiments they might not.

The communication component 1612 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 1612 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 1612 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 1612 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 1612 may operate in accordance with other wireless protocols in other embodiments. The electrical device 1600 may include an antenna 1622 to facilitate wireless communications and/or to receive other wireless communications (such as AM or FM radio transmissions).

In some embodiments, the communication component 1612 may manage wired communications, such as electrical, optical, or any other suitable communication protocols (e.g., IEEE 802.3 Ethernet standards). As noted above, the communication component 1612 may include multiple communication components. For instance, a first communication component 1612 may be dedicated to shorter-range wireless communications such as Wi-Fi or Bluetooth, and a second communication component 1612 may be dedicated to longer-range wireless communications such as global positioning system (GPS), EDGE, GPRS, CDMA, WiMAX, LTE, EV-DO, or others. In some embodiments, a first communication component 1612 may be dedicated to wireless communications, and a second communication component 1612 may be dedicated to wired communications.

The electrical device 1600 may include battery/power circuitry 1614. The battery/power circuitry 1614 may include one or more energy storage devices (e.g., batteries or capacitors) and/or circuitry for coupling components of the electrical device 1600 to an energy source separate from the electrical device 1600 (e.g., AC line power).

The electrical device 1600 may include a display device 1606 (or corresponding interface circuitry, as discussed above). The display device 1606 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 1600 may include an audio output device 1608 (or corresponding interface circuitry, as discussed above). The audio output device 1608 may include any embedded or wired or wirelessly connected external device that generates an audible indicator, such as speakers, headsets, or earbuds.

The electrical device 1600 may include an audio input device 1624 (or corresponding interface circuitry, as discussed above). The audio input device 1624 may include any embedded or wired or wirelessly connected device that generates a signal representative of a sound, such as microphones, microphone arrays, or digital instruments (e.g., instruments having a musical instrument digital interface (MIDI) output). The electrical device 1600 may include a Global Navigation Satellite System (GNSS) device 1618 (or corresponding interface circuitry, as discussed above), such as a Global Positioning System (GPS) device. The GNSS device 1618 may be in communication with a satellite-based system and may determine a geolocation of the electrical device 1600 based on information received from one or more GNSS satellites, as known in the art.

The electrical device 1600 may include another output device 1610 (or corresponding interface circuitry, as discussed above). Examples of the other output device 1610 may include an audio codec, a video codec, a printer, a wired or wireless transmitter for providing information to other devices, or an additional storage device.

The electrical device 1600 may include another input device 1620 (or corresponding interface circuitry, as discussed above). Examples of the other input device 1620 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 1600 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra-mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 1600 may be any other electronic device that processes data. In some embodiments, the electrical device 1600 may comprise multiple discrete physical components. Given the range of devices that the electrical device 1600 can be manifested as in various embodiments, in some embodiments, the electrical device 1600 can be referred to as a computing device or a computing system.

As used in this application and the claims, a list of items joined by the term “and/or” can mean any combination of the listed items. For example, the phrase “A, B and/or C” can mean A; B; C; A and B; A and C; B and C; or A, B and C. As used in this application and the claims, a list of items joined by the term “at least one of” can mean any combination of the listed terms. For example, the phrase “at least one of A, B or C” can mean A; B; C; A and B; A and C; B and C; or A, B, and C. Moreover, as used in this application and the claims, a list of items joined by the term “one or more of” can mean any combination of the listed terms. For example, the phrase “one or more of A, B and C” can mean A; B; C; A and B; A and C; B and C; or A, B, and C.

As used in this application and the claims, the phrase “individual of” or “respective of” following by a list of items recited or stated as having a trait, feature, etc. means that all the items in the list possess the stated or recited trait, feature, etc. For example, the phrase “individual of A, B, or C, comprise a sidewall” or “respective of A, B, or C, comprise a sidewall” means that A comprises a sidewall, B comprises sidewall, and C comprises a sidewall.

The disclosed methods, apparatuses, and systems are not to be construed as limiting in any way. Instead, the present disclosure is directed toward all novel and nonobvious features and aspects of the various disclosed embodiments, alone and in various combinations and subcombinations with one another. The disclosed methods, apparatuses, and systems are not limited to any specific aspect or feature or combination thereof, nor do the disclosed embodiments require that any one or more specific advantages be present or problems be solved.

Theories of operation, scientific principles, or other theoretical descriptions presented herein in reference to the apparatuses or methods of this disclosure have been provided for the purposes of better understanding and are not intended to be limiting in scope. The apparatuses and methods in the appended claims are not limited to those apparatuses and methods that function in the manner described by such theories of operation.

Although the operations of some of the disclosed methods are described in a particular, sequential order for convenient presentation, it is to be understood that this manner of description encompasses rearrangement, unless a particular ordering is required by specific language set forth herein. For example, operations described sequentially may in some cases be rearranged or performed concurrently. Moreover, for the sake of simplicity, the attached figures may not show the various ways in which the disclosed methods can be used in conjunction with other methods.

The following examples pertain to additional embodiments of technologies disclosed herein.

Example 1 is an apparatus comprising: a printed circuit board; an integrated circuit component attached to the printed circuit board; a connector attached to the printed circuit board; an enclosure; and a lid attached to the printed circuit board and the enclosure, wherein the lid and the enclosure define a volume within which the printed circuit board, the integrated circuit component, and at least a portion of the connector are located, wherein attachment of the lid to the enclosure forms a seal between the lid and the enclosure to prevent liquid from entering the volume.

Example 2 comprises the apparatus of Example 1, wherein the seal comprises a gasket.

Example 3 comprises the apparatus of Example 1, wherein the printed circuit board is attached to the lid by one or more first fasteners and the lid is attached to the enclosure by one or more second fasteners.

Example 4 comprises the apparatus of any one of Examples 1-3, wherein the printed circuit board is a first printed circuit board, the apparatus further comprising a second printed circuit board, the connector attached to the second printed circuit board, wherein the integrated circuit component is electrically coupled to the second printed circuit board via the first printed circuit board and the connector.

Example 5 comprises the apparatus of Example 4, wherein the lid is further attached to the second printed circuit board, wherein attachment of the lid to the second printed circuit board forms a seal between the enclosure and the second printed circuit board to prevent liquid from entering the volume through the seal between the enclosure and the second printed circuit board.

Example 6 comprises the apparatus of Example 5, wherein the seal between the lid and the second printed circuit board comprises a gasket positioned between the lid and the second printed circuit board.

Example 7 comprises the apparatus of Example 4, wherein attachment of the lid to the enclosure forms a seal between the enclosure and the first printed circuit board to prevent liquid from entering the volume through the seal between the enclosure and the first printed circuit board.

Example 8 comprises the apparatus of Example 7, wherein the seal between the enclosure and the first printed circuit board comprises a gasket positioned between the lid and the first printed circuit board.

Example 9 comprises the apparatus of any one of Examples 4-8, further comprising a second integrated circuit component attached to the second printed circuit board.

Example 10 is an apparatus comprising: a printed circuit board; an integrated circuit component attached to the printed circuit board; a connector; an enclosure; and a lid attached to the printed circuit board and the enclosure, wherein the lid and the enclosure define a volume within which the integrated circuit component and a first portion of the printed circuit board are located, wherein a second portion of the printed circuit board is located outside of the volume and the connector is attached to the second portion of the printed circuit board, wherein attachment of the lid to the enclosure comprises a first seal and attachment of the lid to the printed circuit board comprises a second seal, the first seal and the second seal to prevent liquid from entering the volume.

Example 11 comprises the apparatus of Example 10, wherein the enclosure comprises: a first portion of the enclosure attached to the lid and the printed circuit board; and a second portion of the enclosure attached to the printed circuit board.

Example 12 comprises the apparatus of Example 10 or 11, wherein the first seal comprises a first gasket and the second seal comprises a second gasket.

Example 13 comprises the apparatus of Example 10, wherein the connector is a first connector, the apparatus further comprising: a second connector attached to the first portion of the printed circuit board; a cable attached to the second connector, the cable extending through an opening in the enclosure; and a third seal positioned at the opening to prevent liquid from entering the volume at the opening.

Example 14 comprises the apparatus of Example 13, wherein the enclosure comprises: a first portion of the enclosure attached to the lid and the printed circuit board; a second portion of the enclosure attached to the printed circuit board; and a third portion of the enclosure attached to the printed circuit board and the second portion of the enclosure.

Example 15 comprises the apparatus of any one of Examples 1-14, further comprising a layer of thermally conductive material positioned between the lid and the integrated circuit component.

Example 16 comprises the apparatus of any one of Examples 1-3 and 10-15, wherein the integrated circuit component is a first integrated circuit component, the apparatus further comprising a second integrated circuit component attached to the printed circuit board.

Example 17 comprises the apparatus of Example 16, wherein the second integrated circuit component is a memory.

Example 18 comprises the apparatus of any one of Examples 1-17, wherein the lid comprises a heat sink.

Example 19 comprises the apparatus of any one of Examples 1-17, further comprising a heat sink attached to the lid.

Example 20 is an apparatus comprising: a printed circuit board; an integrated circuit component attached to the printed circuit board; and a heat sink comprising or attached to a ring that encompasses the integrated circuit component, the ring attached to the printed circuit board, wherein attachment of the ring to the printed circuit board forms a seal between the ring and the printed circuit board to prevent liquid from entering a volume defined by the ring, the heat sink, and the printed circuit board, wherein the integrated circuit component is located within the volume.

Example 21 comprises the apparatus of Example 20, wherein the seal comprises a gasket.

Example 22 comprises the apparatus of Example 20, further comprising a socket, wherein the integrated circuit component is attached to the socket, the integrated circuit component is attached to the printed circuit board via the socket, and the ring further encompasses the socket.

Example 23 is an apparatus comprising: a printed circuit board; a socket attached to the printed circuit board; an integrated circuit component attached to the socket; a plate attached to the printed circuit board, the plate encompassing the socket and the integrated circuit component, the plate comprising or attached to a ring that encompasses the socket and the integrated circuit component; and a heat sink attached to the ring, wherein the plate, the ring, the heat sink and the printed circuit board define a volume, wherein the integrated circuit component is located in the volume, wherein attachment of the plate to the printed circuit board forms a first seal between the ring and the printed circuit board and attachment of the ring to the heat sink forms a second seal between the ring and the heat sink, wherein the first seal and the second seal prevent liquid from entering the volume.

Example 24 comprises the apparatus of Example 23, wherein the first seal comprises a first gasket and the second seal comprises a second gasket.

Example 25 comprises the apparatus of Example 23, the apparatus further comprising a backplate attached to a bottom surface of the printed circuit board, the plate attached to the backplate by a fastener.

Example 26 is an apparatus comprising: a printed circuit board; a socket attached to the printed circuit board; an integrated circuit component attached to the socket; and a heat sink attached to the printed circuit board, wherein a seal is located between the heat sink and the socket that prevents liquid from entering a volume defined by the heat sink and the socket, wherein the integrated circuit component is located within the volume.

Example 27 comprises the apparatus of Example 26, wherein the seal is formed between an inner surface of the heat sink and an outer surface of the socket, the inner surface of the heat sink facing the outer surface of the socket.

Example 28 comprises the apparatus of Example 26, wherein the seal is formed between a bottom surface of the heat sink and a top surface of the socket, the bottom surface of the heat sink facing the top surface of the socket.

Example 29 comprises the apparatus of any one of Examples 26-28, wherein the seal is a first seal, the apparatus further comprising a second seal encompassing a perimeter of a base of the socket, the second seal to prevent liquid from entering a volume between the socket and the printed circuit board.

Example 30 comprises the apparatus of Example 29, wherein an edge of the heat sink contacts the second seal to further prevent liquid from entering a volume between the socket and the printed circuit board.

Example 31 is an apparatus comprising: a printed circuit board; a socket attached to the printed circuit board; an integrated circuit component attached to the socket; a plate attached to the printed circuit board; a heat sink; a ring encompassing the socket, the integrated circuit component, and the plate, wherein the ring comprises a ledge positioned between the plate and the printed circuit board; and a cap attached to the ring, wherein attachment of the cap to the ring creates a seal between the ring and the heat sink to prevent liquid from entering a volume defined by the heat sink, the ring, and the printed circuit board, wherein the integrated circuit component and the socket are located within the volume.

Example 32 is an apparatus comprising: a printed circuit board; a socket attached to the printed circuit board; an integrated circuit component attached to the socket; a plate attached to the printed circuit board, the plate encompassing the socket; a heat sink attached to the plate; and a ring comprising a wall and a ledge, the ledge of the ring positioned between the plate and the printed circuit board, the wall of the ring encompassing the socket and the integrated circuit component, wherein the wall of the ring is positioned between the plate and the socket, wherein a seal is positioned between the ring and the heat sink that prevents liquid from entering a volume defined by the wall of the ring, the heat sink, and the printed circuit board, wherein the integrated circuit component and the socket are located within the volume.

Example 33 comprises the apparatus of Example 31 or 32, further comprising a backplate attached to a bottom surface of the printed circuit board, the plate attached to the backplate by a fastener.

Example 34 is an apparatus comprising: a printed circuit board; a socket attached to the printed circuit board; an integrated circuit component attached to the socket, the integrated circuit component comprising an integrated heat spreader; a plate attached to the printed circuit board; a heat sink located on the integrated circuit component; and a ring comprising a top ledge, a wall, and a bottom ledge, wherein the bottom ledge of the ring is positioned between the plate and the printed circuit board, the wall of the ring encompasses the socket and the integrated circuit component, the wall of the ring is positioned between the plate and the socket, wherein a seal between the top ledge of the ring and the integrated heat spreader prevents liquid from entering a volume defined by the wall of the ring, the integrated circuit component, and the printed circuit board, wherein the integrated circuit component is located within the volume.

Example 35 comprises the apparatus of Example 34, wherein the seal is positioned between an end of the top ledge of the ring and a shoulder of the integrated heat spreader.

Example 36 comprises the apparatus of Example 34 or 35, wherein the seal is a first seal, the apparatus further comprising a second seal between the top ledge and the heat sink that further prevents liquid from entering the volume.

Example 37 comprises the apparatus of any one of Examples 34-36, further comprising a backplate attached to a bottom surface of the printed circuit board via attachment of the backplate to the plate.

Example 38 comprises the apparatus of any one of Examples 26-28 and 34-35, wherein the seal comprises a gasket.

Example 39 comprises the apparatus of any one of Examples 20-38, wherein a layer comprising thermal conductive material is positioned between the heat sink and integrated circuit component.

Example 40 comprises the apparatus of any one of Examples 15 and 39, wherein the thermally conductive material comprises silver thermal compound, thermal grease, phase change materials, indium foils, graphite sheets, or graphite sheets.

Example 41 comprises the apparatus of any one of Examples 20-40, further comprising a memory module attached to the printed circuit board.

Example 42 comprises the apparatus of any one of Examples 18-41, wherein the heat sink comprises a heat pipe, a cold plate, or a vapor chamber.

Example 43 comprises the apparatus of any one of Examples 1-8, 10-15, 20-42, wherein the integrated circuit component comprises a processor.

Example 44 comprises the apparatus of any one of Examples 1-8, 10-15, 20-42, wherein the integrated circuit component comprises a graphics processing unit.

Example 45 comprises the apparatus of any one of Examples 1-44, further comprising a tank at least partially filled with cooling liquid, wherein the integrated circuit component is submerged in the cooling liquid.

Example 46 comprises the apparatus of Example 45, wherein the cooling liquid is a dielectric liquid.

Example 47. A system comprising: a printed circuit board; an integrated circuit component attached to the printed circuit board; an assembly comprising the printed circuit board and integrated circuit component; a conformal coating covering one or more external surfaces of the assembly, wherein the conformal coating is: (1) hydrophobic or super-hydrophobic as well as oleophobic or super-oleophobic; (2) amphiphobic or super-amphiphobic; (3) omniphobic; or (4) any combination of (1), (2), and (3); and a tank at least partially filled with a liquid, wherein the assembly is immersed in the liquid.

Example 48. The system of Example 47, wherein the conformal coating is omniphobic.

Example 49. The system of Example 47, wherein the conformal coating is amphiphobic.

Example 50. The system of Example 47, wherein the conformal coating has a water contact angle and an oil contact angle of greater than about 90 degrees.

Example 51. The system of Example 47, wherein the conformal coating is super-amphiphobic.

Example 52. The system of Example 47, wherein the conformal coating has a probe liquid contact angle of a greater than about 150 degrees.

Example 53. The system of Example 47, wherein the conformal coating is hydrophobic or super-hydrophobic as well as oleophobic or super-oleophobic.

Example 54. The system of Example 47, wherein the conformal coating has a water contact angle of greater than about 90 degrees.

Example 55. The system of Example 47, wherein the conformal coating has a water contact angle of greater than about 150 degrees.

Example 56. The system of Example 47, wherein the conformal coating has a water contact angle in a range of about 105 degrees to about 120 degrees and a contact angle of a probe liquid droplet of a short chain alkane of greater than about 60 degrees on a solid surface.

Example 57. The system of Example 47, wherein the conformal coating has a water contact angle in a range of about 105 degrees to about 120 degrees and a contact angle of a probe liquid droplet of a short chain alkane of greater than about 150 degrees.

Example 58. The system of any one of Examples 47 and 53-57, wherein the conformal coating comprises a fluorinated compound.

Example 59. The system of any one of Examples 47 and 53-57, wherein the conformal coating comprises fluorine and another element.

Example 60. The system of Example 47, wherein the conformal coating comprises a parylene coating.

Example 61. The system of any one of Examples 47 and 51-52, wherein the conformal coating comprises a fluorinated compound comprising nanoparticles comprising: silicon and oxygen; titanium and oxygen; copper and oxygen; zinc and oxygen; calcium, carbon, and oxygen; aluminum and oxygen; magnesium and oxygen; or carbon.

Example 62. The system of any one of Examples 47 and 51-52, wherein the conformal coating comprises sodium, calcium, aluminum, magnesium, silicon, oxygen, and hydrogen.

Example 63. The system of any one of Examples 47 and 51-52, wherein the conformal coating further comprises fluorine.

Example 64. A system, comprising: a printed circuit board; an integrated circuit component attached to the printed circuit board; an assembly comprising the printed circuit board and integrated circuit component; and a conformal coating covering one or more external surfaces of the assembly, wherein the conformal coating comprises a non-oleophobic polymeric material that does not comprise fluorine.

Example 65. The system of Example 64, wherein the non-oleophobic polymeric material is polyurethane, epoxy, or polyimide.

Example 66. The system of any one of Examples 64-65, wherein the assembly further comprises a connector attached to the printed circuit board.

Example 67. The system of any one of Examples 47-66, wherein the integrated circuit component is a first integrated circuit component, the assembly further comprising a second integrated circuit component connected to the printed circuit board.

Example 68. The system of Example 67, wherein the second integrated circuit component is a memory.

Example 69. The system of any one of Examples 47-68, wherein the conformal coating has a thickness of about 1 micron to about 50 microns.

Example 70. The system of any one of Examples 47-69, wherein the integrated circuit component comprises a processor.

Example 71. The system of any one of Examples 47-69, wherein the integrated circuit component comprises a graphics processing unit.

Example 72. The system of any one of Examples 47-69, further comprising a tank at least partially filled with cooling liquid, wherein the integrated circuit component is submerged in the cooling liquid.

Example 73. The system of Example 72, wherein the cooling liquid is a dielectric liquid.

Example 74. A system comprising: a first printed circuit board; an integrated circuit component attached to the first printed circuit board; a connector; a second printed circuit board, the connector attached to the first printed circuit board and the second printed circuit board; an enclosure; a tank at least partially filled with a liquid; and a lid attached to the first printed circuit board and the enclosure, wherein the lid and the enclosure define a volume within which the first printed circuit board, the integrated circuit component, and at least a portion of the connector are located, wherein attachment of the lid to the first printed circuit board forms a seal positioned between the lid and the first printed circuit board, the integrated circuit component is submerged in the liquid, and the seal prevents the liquid from entering the volume.

Example 75. The system of Example 74, wherein the integrated circuit component is electrically coupled to the second printed circuit board via the first printed circuit board and the connector.

Example 76. The system of Example 74, wherein the seal comprises a gasket positioned between the lid and the enclosure.

Example 77. The system of any one of Examples 74-76, wherein the seal is a first seal and the lid is attached to the second printed circuit board, wherein attachment of the lid to the second printed circuit board comprises a second seal between the enclosure and the second printed circuit board to prevent liquid from entering the volume.

Example 78. The system of Example 77, wherein the second seal comprises a gasket positioned between the lid and the second printed circuit board.

Example 79. The system of any one of Examples 74-76, wherein the seal is a first seal, the attachment of the lid to the enclosure further comprises a second seal between the enclosure and the first printed circuit board to prevent liquid from entering the volume.

Example 80. The system of Example 79, wherein the second seal comprises a gasket positioned between the lid and the first printed circuit board.

Example 81. A system comprising: a printed circuit board; an integrated circuit component attached to the printed circuit board; a connector; a second printed circuit board, the connector attached to the second printed circuit board; an enclosure; a tank at least partially filled with a liquid; and a lid attached to the printed circuit board and the enclosure, wherein the lid and the enclosure define a volume within which the integrated circuit component and first a portion of the printed circuit board are located, wherein a second portion of the printed circuit board is located outside of the volume and the connector is attached to the second portion of the printed circuit board, wherein the integrated circuit component is located in the tank and submerged in the liquid, wherein attachment of the lid to the enclosure comprises a first seal and attachment of the lid to the printed circuit board comprises a second seal, the first seal and the second seal to prevent liquid from entering the volume.

Example 82. The system of Example 81, wherein the enclosure comprises: a first enclosure portion attached to the lid; and a second enclosure portion attached to the printed circuit board.

Example 83. The system of Example 81 or 82, wherein the first seal comprises a first gasket and the second seal comprises a second gasket.

Example 84. The system of any one of Examples 81-83, further comprising: a second connector attached to the printed circuit board; a cable attached to the second connector, the cable extending through an opening in the enclosure; and a third seal positioned at the opening to prevent liquid from entering the volume.

Example 85. The system of any one of Examples 81-84, further comprising a layer of thermally conductive material positioned between the lid and the integrated circuit component.

Example 86. The system of any one of Examples 81-85, wherein the integrated circuit component is a first integrated circuit component, the system further comprising a second integrated circuit component attached to the printed circuit board.

Example 87. The system of Example 86, wherein the second integrated circuit component is a memory.

Example 88. The system of any one of Examples 68-87, wherein the lid comprises a heat sink.

Example 89. The system of any one of Examples 68-87, further comprising a heat sink attached to the lid.

Example 90. A system comprising: a printed circuit board; an integrated circuit component attached to a printed circuit board; a tank at least partially filled with a liquid; and a heat sink comprising or attached to a ring that encompasses the integrated circuit component, the ring attached to the printed circuit board, wherein attachment of the ring to the printed circuit board forms a seal between the ring and the printed circuit board to prevent liquid from entering a volume defined by the ring, the heat sink, and the printed circuit board, wherein the integrated circuit component is located within the volume, wherein the integrated circuit component is located in the tank and submerged in the liquid.

Example 91. The system of Example 90, wherein the seal comprises a gasket.

Example 92. The system of Example 90, further comprising a socket, wherein the integrated circuit component is attached to the socket, the integrated circuit component is attached to the printed circuit board via the socket, and the ring further encompasses the socket.

Example 93. A system comprising: a printed circuit board; a socket attached to the printed circuit board; an integrated circuit component attached to the socket; a tank at least partially filled with a liquid; a plate attached to the printed circuit board, the plate encompassing the socket and the integrated circuit component, the plate comprising or attached to a ring that encompasses the socket and the integrated circuit component; a ring located on a top surface of the printed circuit board and encompassing the integrated circuit component, wherein attachment of the ring to the printed circuit board forms a first seal between the ring and the printed circuit board; and a heat sink attached to the ring, wherein the plate, the ring, the heat sink and the printed circuit board define a volume, wherein the integrated circuit component is located in the volume, wherein attachment of the plate to the printed circuit board forms a first seal between the ring and the printed circuit board and attachment of the ring to the heat sink forms a second seal between the ring and the heat sink, wherein the integrated circuit component is located in the tank and submerged in the liquid wherein the first seal and the second seal prevent liquid from entering the volume.

Example 94. The system of Example 93, wherein the first seal comprises a first gasket and the second seal comprises a second gasket.

Example 95. A system comprising: a printed circuit board; a socket attached to the printed circuit board; an integrated circuit component attached to the socket; a tank at least partially filled with a liquid; and a heat sink attached to the printed circuit board, wherein attachment of the heat sink to the printed circuit board forms a seal between the heat sink and the socket that prevents liquid from entering a volume defined by the heat sink and the socket, wherein the integrated circuit component is located within the volume, wherein the integrated circuit component is located in the tank and submerged in the liquid.

Example 96. The system of Example 95, wherein the seal is formed between an inner surface of the heat sink and an outer surface of the socket, the inner surface of the heat sink facing the outer surface of the socket.

Example 97. The system of Example 95, wherein the seal is formed between a bottom surface of the heat sink and a top surface of the socket, the bottom surface of the heat sink facing the top surface of the socket.

Example 98. The system of any one of Examples 95-97, the system further comprising underfill material encompassing a perimeter of the socket where the socket meets the printed circuit board, the underfill material to prevent liquid from entering a volume between the socket and the printed circuit board.

Example 99. The system of Example 98, wherein the seal is a first seal and an edge of the heat sink contacts the underfill material to create a second seal to further prevent liquid from entering the volume.

Example 100. A system comprising: a printed circuit board; a socket attached to the printed circuit board; an integrated circuit component attached to the socket; a plate attached to the socket; a heat sink attached to the plate; a tank at least partially filled with a liquid; a ring encompassing the socket, the integrated circuit component, and the plate, wherein the ring comprises a ledge positioned between the plate and the printed circuit board; and a cap attached to the ring, wherein attachment of the cap to the ring creates a seal to prevent liquid from entering a volume defined by the plate, the heat sink, the ledge of the ring, and the printed circuit board, wherein the integrated circuit component is located within the volume, wherein the integrated circuit component is located in the tank and submerged in the liquid.

Example 101. A system comprising: a printed circuit board; a socket attached to the printed circuit board; an integrated circuit component attached to the socket; a plate attached to the printed circuit board, the plate encompassing the socket; a heat sink attached to the plate; a tank at least partially filled with a liquid; and a ring comprising a wall and a ledge, the ledge of the ring positioned between the plate and the printed circuit board, the wall of the ring encompassing the socket and the integrated circuit component, wherein the plate is positioned outside of the wall of the ring, wherein attachment of the heat sink to the ring creates a seal to prevent liquid from entering a volume defined by the wall of the ring, the heat sink, and the printed circuit board, wherein the integrated circuit component is located within the volume, wherein the integrated circuit component is located in the tank and submerged in the liquid.

Example 102. A system comprising: a printed circuit board; a socket attached to the printed circuit board; an integrated circuit component attached to the socket, the integrated circuit component comprising an integrated heat spreader; a plate attached to the printed circuit board; a heat sink located on the integrated circuit component; a tank at least partially filled with a liquid; and a ring comprising a top ledge, a wall, and a bottom ledge, wherein the bottom ledge of the ring is positioned between the plate and the printed circuit board, the wall of the ring encompasses the socket and the integrated circuit component, the wall of the ring is positioned between the plate and the socket, wherein attachment of the heat sink to the ring creates a seal to prevent liquid from entering a volume defined by the wall of the ring, the heat sink, and the printed circuit board, wherein the integrated circuit component is located within the volume, wherein the integrated circuit component is located in the tank and submerged in the liquid.

Example 103. The system of Example 102, wherein the seal is a first seal, the top ledge of the wall is further attached to the heat sink, and attachment of the top ledge of the wall of the ring to the heat sink creates a second seal to prevent liquid from entering the volume.

Example 104. The system of any one of Examples 81-103, wherein the seal comprises a gasket.

Example 105. The system of Example 85, wherein the thermally conductive material comprises silver thermal compound, thermal grease, phase change materials, indium foils, or graphite sheets.

Example 106. The system of any one of Examples 90-105, further comprising one or more memory modules or memories attached to the printed circuit board.

Example 107. The system of any one of Examples 74-106, wherein the integrated circuit component comprises a processor.

Example 108. The system of any one of Examples 74-106, wherein the integrated circuit component comprises a graphics processing unit.

Example 109. The system of any one of Examples 74-106, wherein the liquid is a dielectric liquid.

Example 110 is an apparatus comprising: a first printed circuit board; an integrated circuit component attached to the first printed circuit board; a second printed circuit board; a tank at least partially filled with a liquid, the first printed circuit board and the integrated circuit component submerged in the liquid; an enclosing means to enclose the first printed circuit board and the integrated circuit component in a volume; and a sealing means to prevent the liquid from entering the volume.

Example 111 is an apparatus comprising: a printed circuit board; an integrated circuit component comprising an integrated heat spreader, the integrated circuit component attached to the printed circuit board; a socket, the integrated circuit component attached to the socket; a heat sink; a tank at least partially filled with a liquid; an enclosure means to enclosure the integrated circuit component and the socket in a volume; and a sealing means to prevent the liquid from entering the volume.

Example 112 comprises the apparatus of any one of Examples 110-111, wherein the integrated circuit component comprises a processor.

Example 113 comprises the apparatus of any one of Examples 110-111, wherein the integrated circuit component comprises a graphics processing unit.

Example 114 is a method comprising: inserting a subassembly into an enclosure, the subassembly comprising a printed circuit board, an integrated circuit component, and a connector, wherein the printed circuit board and the connector are attached to the printed circuit board, and a portion of the connector extends through an opening in the enclosure; and attaching a lid to the enclosure, the lid and the enclosure defining a volume within which the integrated circuit component and the printed circuit board are located, wherein attachment of the lid to the enclosure forms a seal to keep liquid out of the volume.

Example 115. The method of Example 114, wherein the printed circuit board is a first printed circuit board, the method further comprising attaching the connector to a second printed circuit board.

Example 116. The method of Example 114, further comprising attaching the lid to a second printed circuit board.

Example 117. The method of Example 114, further comprising inserting the subassembly, lid, and enclosure into a tank at least partially filled with liquid, wherein the subassembly, the lid, and the enclosure are submerged in the liquid.

Example 118. The method of any one of Examples 114-117, wherein the seal comprises a gasket.

1. An apparatus comprising:
a printed circuit board;
an integrated circuit component attached to the printed circuit board;
a connector attached to the printed circuit board;
an enclosure; and
a lid attached to the printed circuit board and the enclosure, wherein the lid and the enclosure define a volume within which the printed circuit board, the integrated circuit component, and at least a portion of the connector are located, wherein attachment of the lid to the enclosure forms a seal between the lid and the enclosure to prevent liquid from entering the volume.

2. The apparatus of claim 1, wherein the printed circuit board is a first printed circuit board, the apparatus further comprising a second printed circuit board, the connector attached to the second printed circuit board, wherein the integrated circuit component is electrically coupled to the second printed circuit board via the first printed circuit board and the connector.

3. The apparatus of claim 2, wherein the lid is further attached to the second printed circuit board, wherein attachment of the lid to the second printed circuit board forms a seal between the enclosure and the second printed circuit board to prevent liquid from entering the volume through the seal between the enclosure and the second printed circuit board.

4. The apparatus of claim 2, wherein attachment of the lid to the enclosure forms a seal between the enclosure and the first printed circuit board to prevent liquid from entering the volume through the seal between the enclosure and the first printed circuit board.

5. The apparatus of claim 1, wherein the integrated circuit component is a first integrated circuit component, the apparatus further comprising a second integrated circuit component attached to the printed circuit board.

6. The apparatus of claim 1, wherein the lid comprises a heat sink.

7. The apparatus of claim 1, further comprising a heat sink attached to the lid.

8. The apparatus of claim 1, wherein the integrated circuit component comprises a processor.

9. The apparatus of claim 1, further comprising a tank at least partially filled with dielectric liquid, wherein the integrated circuit component is submerged in the dielectric liquid.

10. An apparatus comprising:
a printed circuit board;
a socket attached to the printed circuit board;
an integrated circuit component attached to the socket, the integrated circuit component comprising an integrated heat spreader;
a plate attached to the printed circuit board;
a heat sink located on the integrated circuit component; and
a ring comprising a top ledge, a wall, and a bottom ledge, wherein the bottom ledge of the ring is positioned between the plate and the printed circuit board, the wall of the ring encompasses the socket and the integrated circuit component, the wall of the ring is positioned between the plate and the socket, wherein a seal between the top ledge of the ring and the integrated heat spreader prevents liquid from entering a volume defined by the wall of the ring, the integrated circuit component, and the printed circuit board, wherein the integrated circuit component is located within the volume.

11. The apparatus of claim 10, wherein the seal is positioned between an end of the top ledge of the ring and a shoulder of the integrated heat spreader.

12. The apparatus of claim 10, wherein the seal is a first seal, the apparatus further comprising a second seal between the top ledge and the heat sink that further prevents liquid from entering the volume.

13. The apparatus of claim 10, wherein the integrated circuit component comprises a processor.

14. The apparatus of claim 10, further comprising a tank at least partially filled with dielectric liquid, wherein the integrated circuit component is submerged in the dielectric liquid.

15. A system comprising:
a printed circuit board;
an integrated circuit component attached to the printed circuit board;
an assembly comprising the printed circuit board and integrated circuit component;
a conformal coating covering one or more external surfaces of the assembly, wherein the conformal coating is: (1) hydrophobic or super-hydrophobic as well as oleophobic or super-oleophobic; (2) amphiphobic or super-amphiphobic; (3) omniphobic; or (4) any combination of (1), (2), and (3; and
a tank at least partially filled with a liquid, wherein the assembly is immersed in the liquid.

16. The system of claim 15, wherein the conformal coating is hydrophobic or super-hydrophobic as well as oleophobic or super-oleophobic.

17. The system of claim 15, wherein the conformal coating comprises a fluorinated compound.

18. The system of claim 15, wherein the conformal coating comprises a parylene coating.

19. The system of claim 15, wherein the conformal coating comprises a fluorinated compound comprising nanoparticles comprising:
silicon and oxygen;
titanium and oxygen;
copper and oxygen;
zinc and oxygen;
calcium, carbon, and oxygen;
aluminum and oxygen;
magnesium and oxygen; or
carbon.

20. The system of claim 15, wherein the integrated circuit component comprises a processor, the system further comprising a tank at least partially filled with dielectric liquid, wherein the integrated circuit component is submerged in the dielectric liquid.
